(19) United States
(12) Patent Application Publication
(10) Pub. No.: US 2026/0293295 A1
(43) Pub. Date: Sep. 24, 2026

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Mao-Lin HUANG, Hsinchu (TW); Li-Yang CHUANG, Hsinchu (TW); Hsin-Jung LEE, Hsinchu (TW); Chia-Cheng TSAI, Hsinchu (TW); Kuo-Cheng CHIANG, Hsinchu (TW); Chih-Hao WANG, Hsinchu (TW)

(73) Assignee: Taiwan Semiconductor Manufacturing Company, Ltd., Hsinchu (TW)

(21) Appl. No.: 19/086,793

(22) Filed: Mar. 21, 2025

(51) Int. Cl. H10D 84/83; H10D 84/01

(52) U.S. Cl. CPC H10D 84/8311; H10D 84/0128; H10D 84/0142; H10D 84/83138; H10D 84/832

(57) ABSTRACT

According to the present disclosure, a semiconductor structure includes a plurality of first active channels vertically stacked to each other and a plurality of second active channels vertically stacked to each other. In an embodiment, the number of the first active channels and the number of the second active channels are different. As a result, the effective capacitance may be decreased to lead to power efficiency improvement by hybrid sheet approach.

### BACKGROUND

A semiconductor structure includes a plurality of transistors, not all transistors require the same power. For example, some transistors need smaller power, while others transistors need greater power. Thus, how to design transistors for different power requirements is one of the goals of industry players in this technical field.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 1Q_c illustrate schematic diagrams of manufacturing processes of a semiconductor structure according to an embodiment of the present disclosure;

FIGS. 2A_a to 2E_b illustrate schematic diagrams of manufacturing processes of a semiconductor structure according to another embodiment of the present disclosure;

FIGS. 3A_a to 3J_c illustrate schematic diagrams of manufacturing processes of a semiconductor structure according to another embodiment of the present disclosure; and

FIGS. 4A_a to 4F_b illustrate schematic diagrams of manufacturing processes of a semiconductor structure according to another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

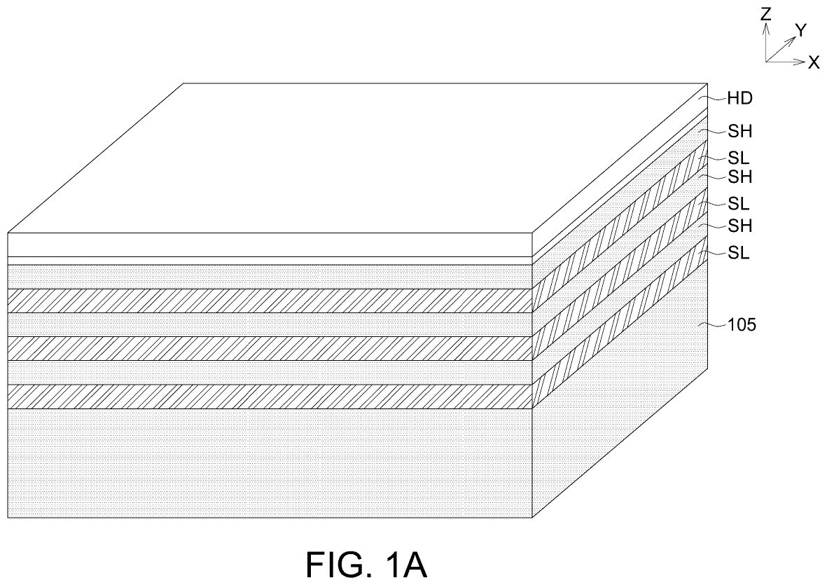

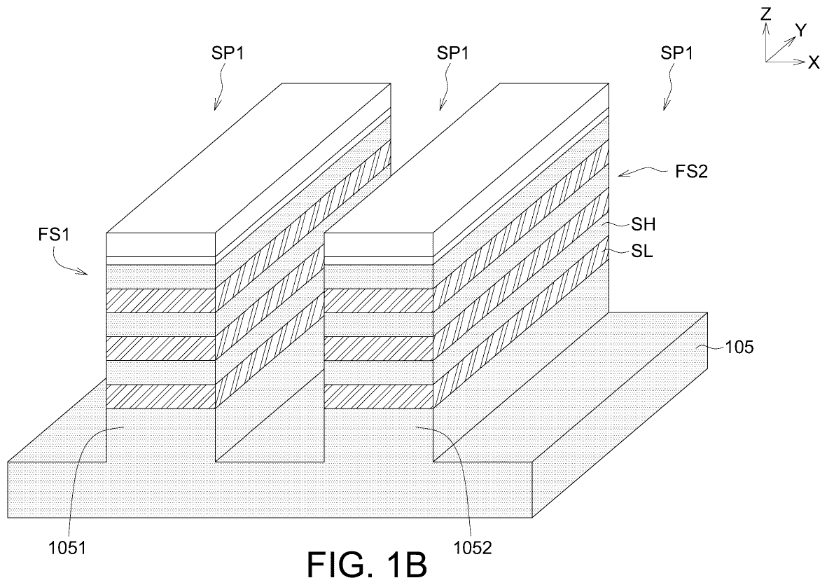

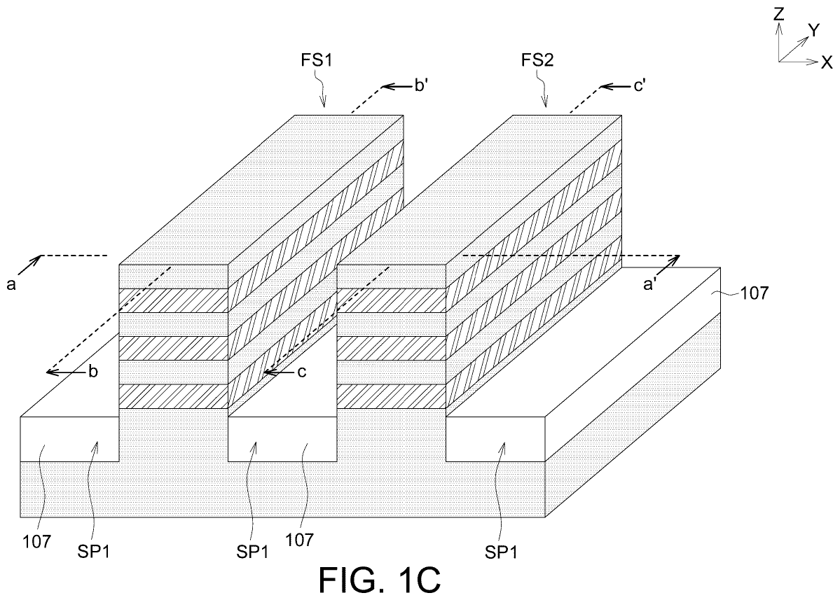

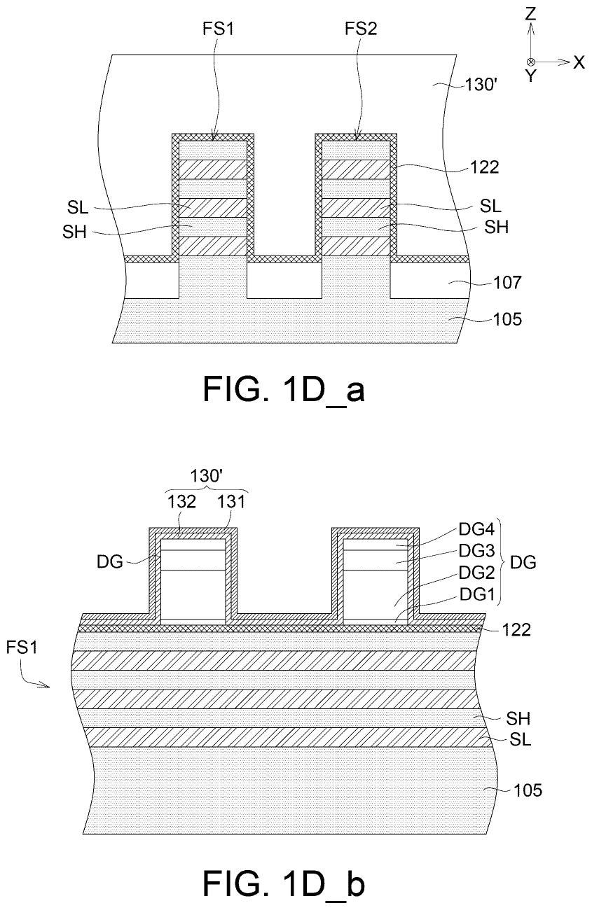

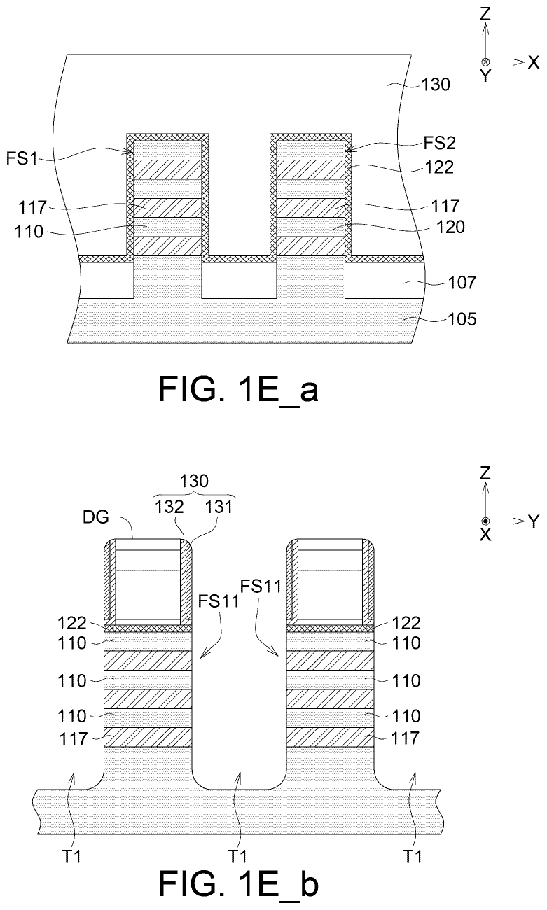

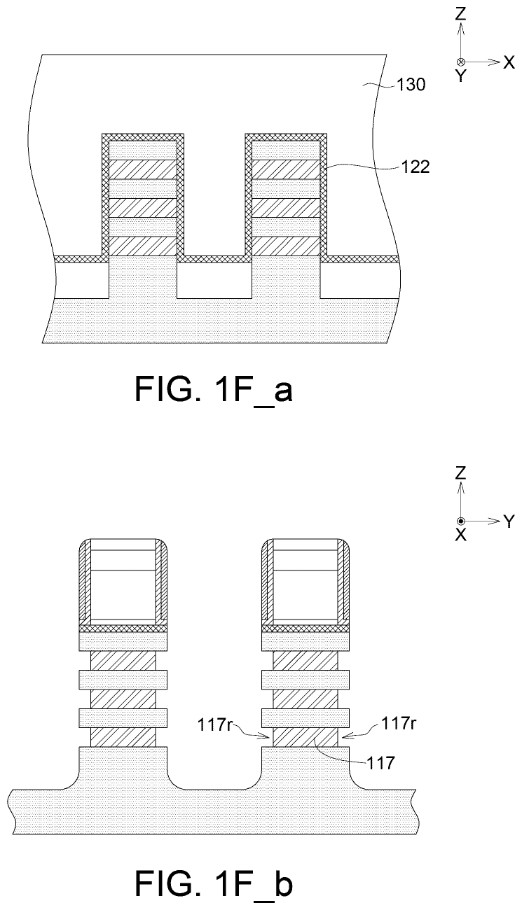

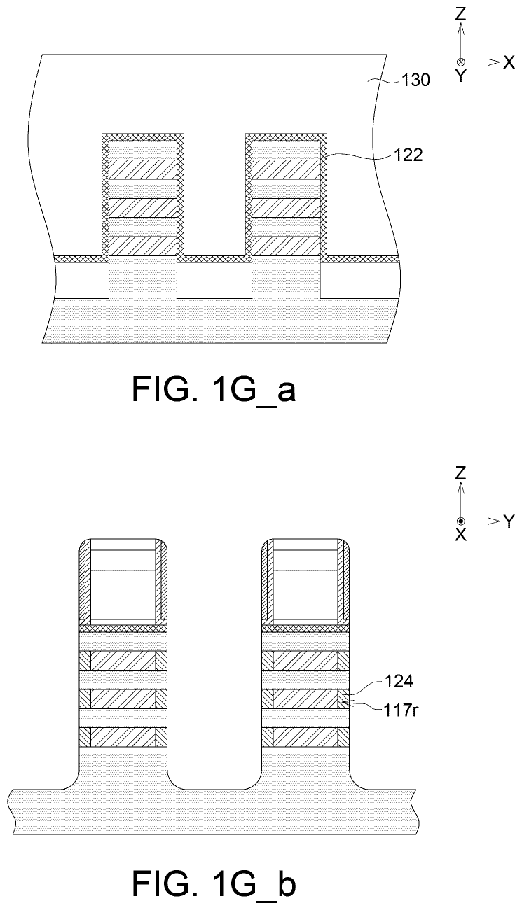

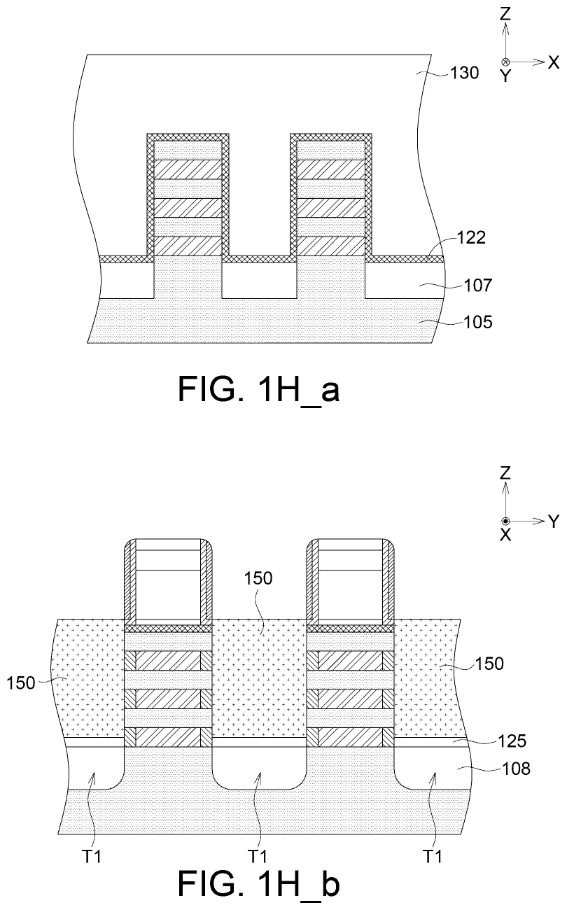

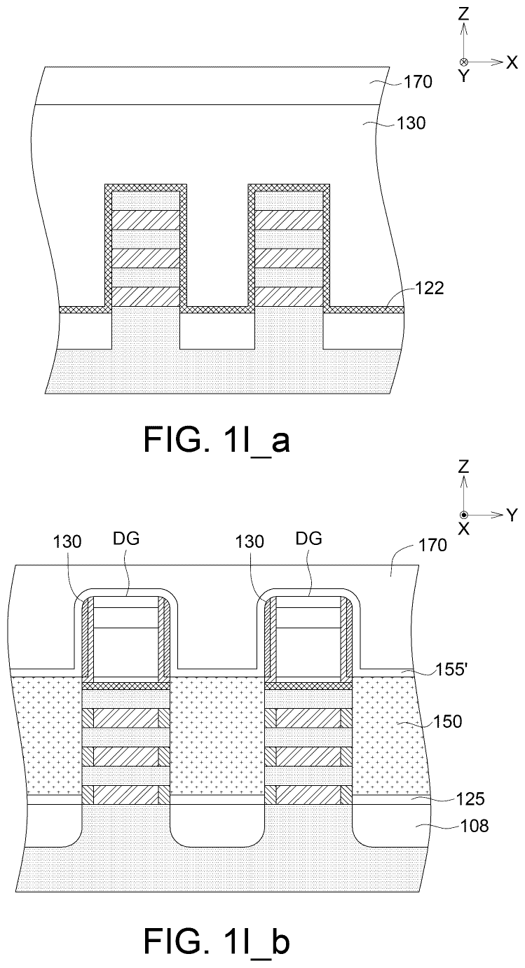

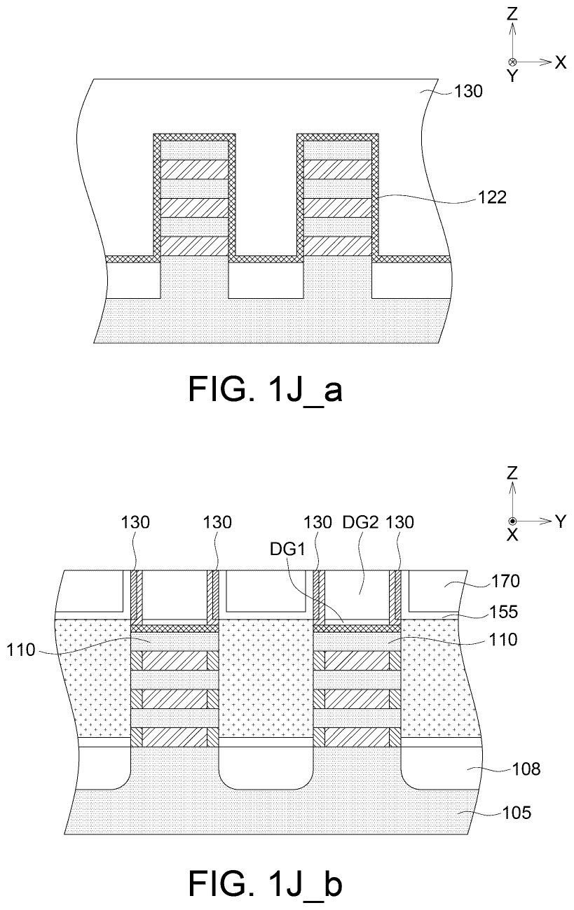

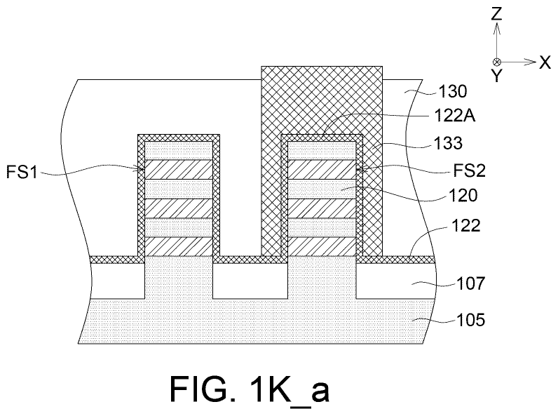

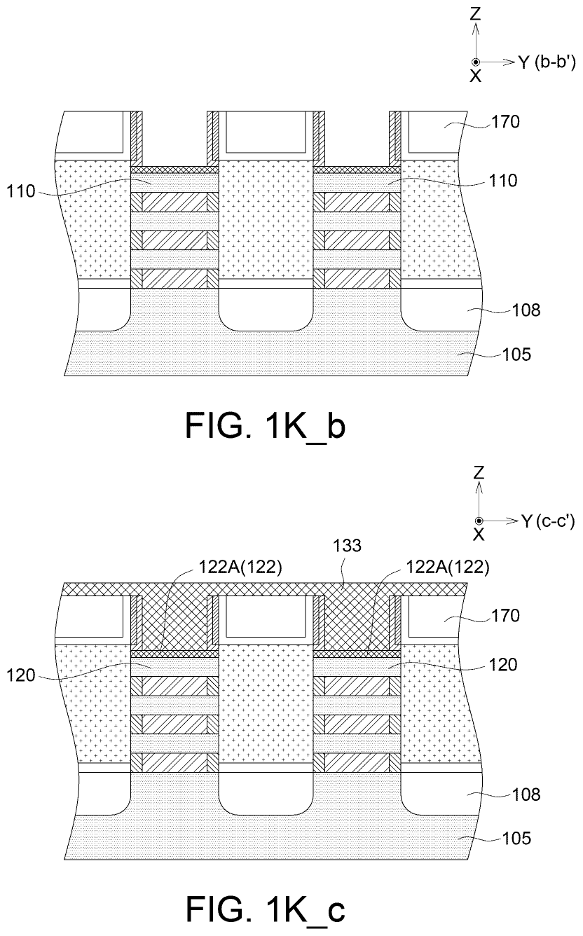

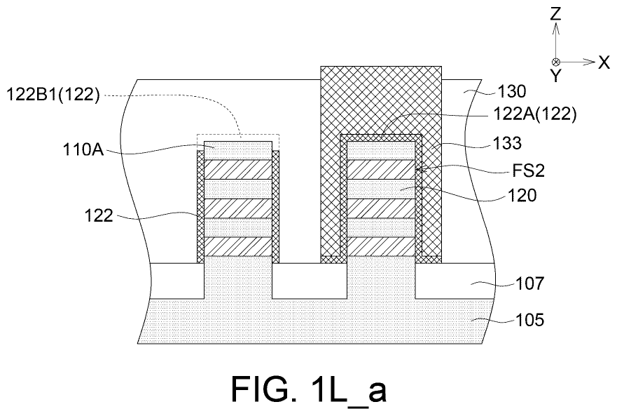

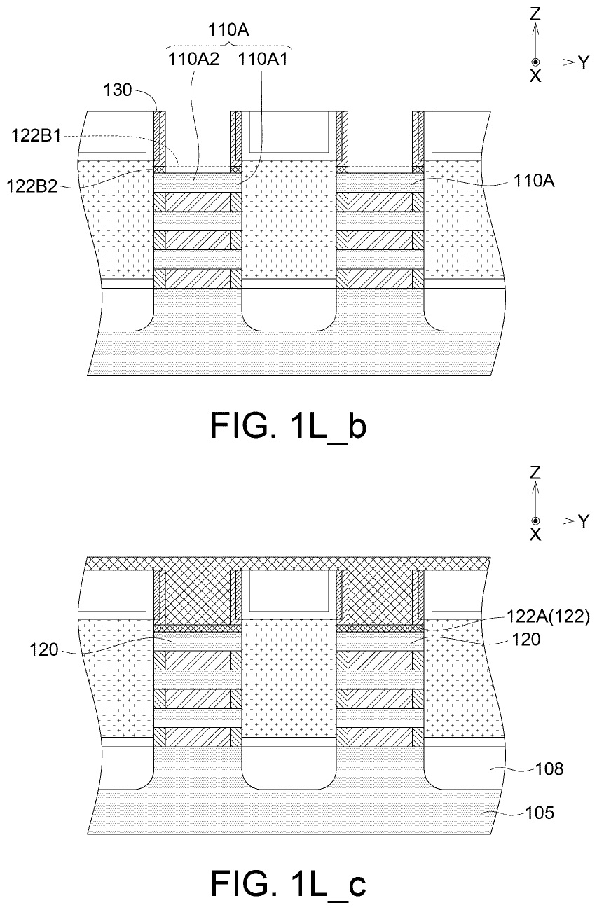

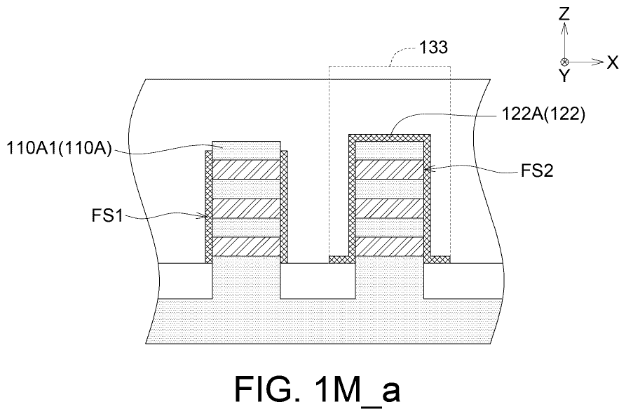

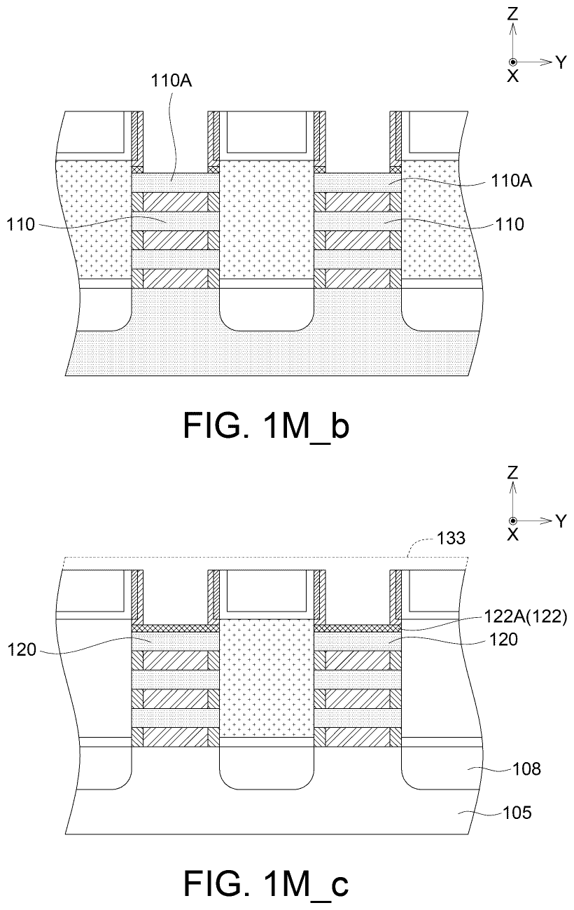

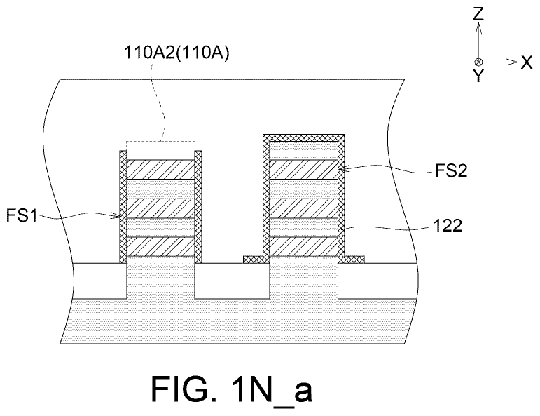

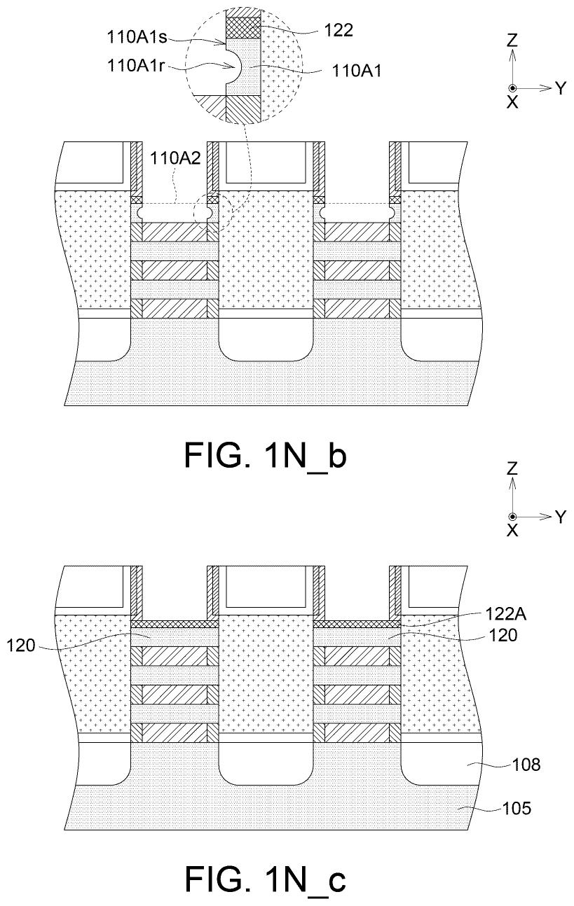

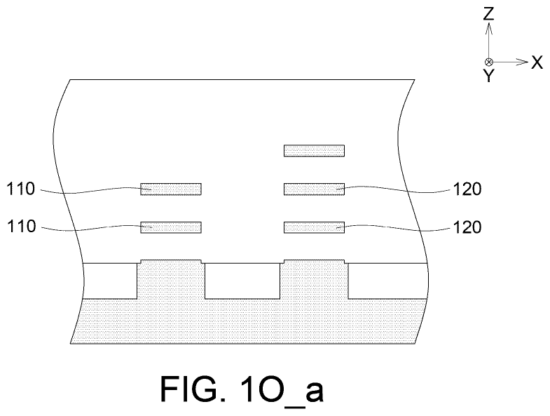

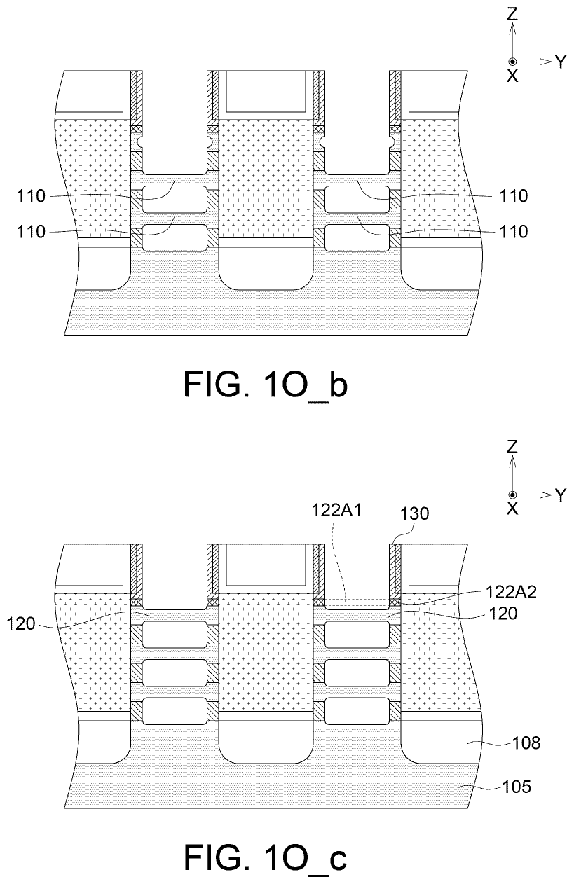

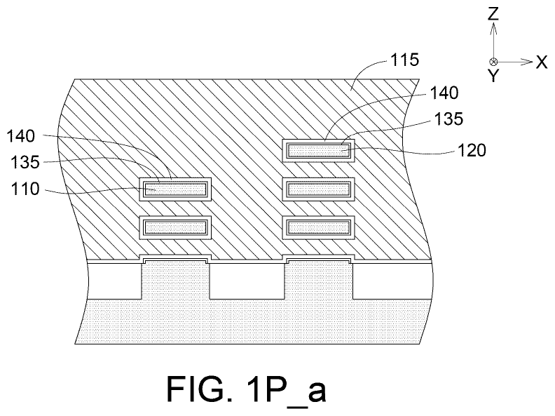

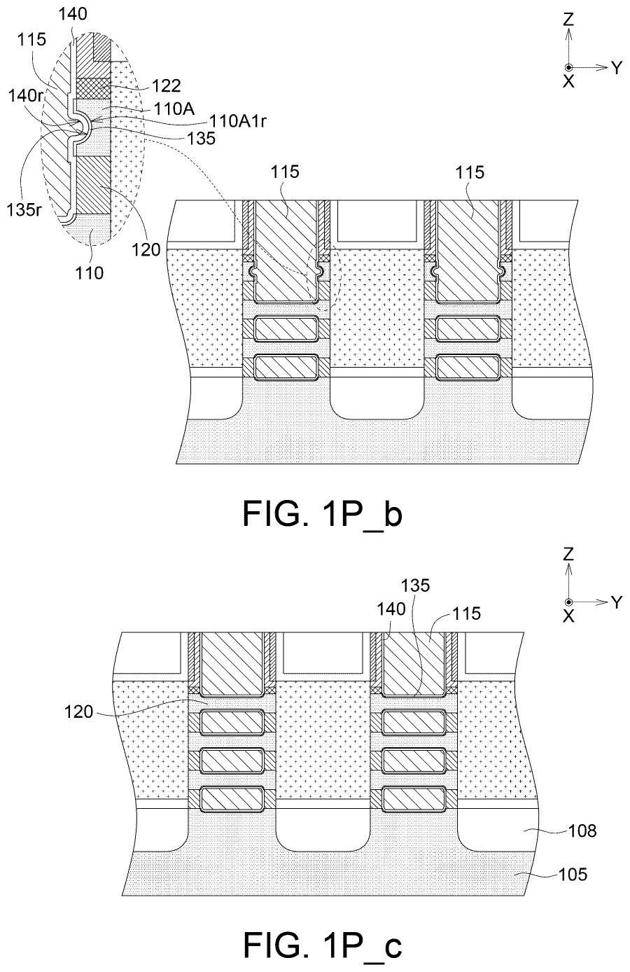

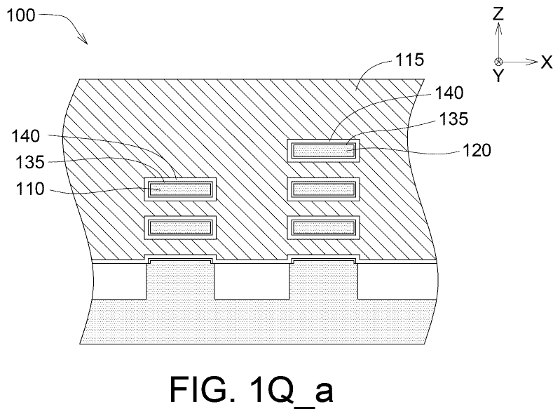

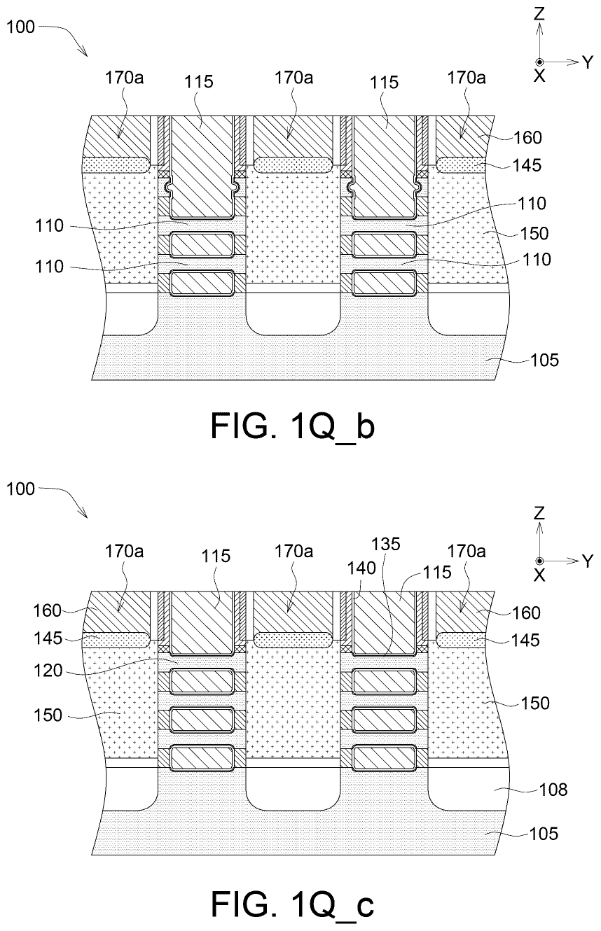

FIGS. 1A to 1Q_c illustrate schematic diagrams of manufacturing processes of a semiconductor structure 100 according to an embodiment of the present disclosure.

As illustrated in FIG. 1A, a superlattice structure including a plurality of active channel layers SH and a plurality of interposer layers SL over a substrate 105 is formed by epitaxy process, for example, molecular beam epitaxy (MBE), metalorganic chemical vapor deposition (MOCVD) or other suitable epitaxial growth processes. The two adjacent active channel layers SH are spaced by one interposer layer SL, or the two adjacent interposer layers SL are spaced by one active channel layer SH. The substrate 105 may be formed of a material including, for example, Si, SiGe, Ge, InGaAs, AlGaAs, SiO₂ (SOI wafer). The substrate 105 is, for example, a wafer. The interposer layer SL may be a sacrificial layer which will be removed in subsequent process. The active channel layers SH may be formed of a material including, for example, Si, SiGe, Ge, GaAs, InGaAs, 2D materials MoS, WS2, etc., and the active channel layer SH has a thickness ranging between 1 nanometer (nm) and 10 nm. The interposer layer SL may be formed of a material including, for example, SiGe, Ge, Si, InGaAs, AlGaAs, etc., and the interposer layer SL has a thickness ranging between 1 nm and 10 nm. Then, a hard mask HD over the superlattice structure is formed by using, for example, deposition.

Then, as illustrated in FIG. 1B, a portion of each active channel layer SH, a portion of each interposer layer SL and a portion of the substrate 105 are removed through the patterned hard mask HD by using etching, for example. A remaining portion of the active channel layers SH and a remaining portion of the interposer layers SL form a plurality of active structures (or referred to as “OD (oxide diffusion) region”), for example, a first active structure FS1 and a second active structure FS2. There is trench SP1 between two adjacent active structures, and the trenches SP1 extend to a portion of the substrate 105 to form a plurality of protrusions, for example, a first protrusion 1051 and a second protrusion 1052, wherein the first active structure FS1 is located on the first protrusion 1051, and the second active structure FS2 is located on the second protrusion 1052.

Then, as illustrated in FIG. 1C, the patterned hard mask HD is removed by using, for example, etching, etc. Then, an oxide layer 107 in a bottom of the trench SP1 formed by using, deposition, photolithography, etching, etc. The oxide layer 107 may be formed of a material including silicon oxide, silicon nitride, silicon carbide, FSG (fluorosilicate glass), low dielectric constant material or other suitable dielectric material.

In processes of the oxide layer 107, the dielectric material may be formed in the trenches SP1 by using, for example, deposition such as hot growth, CVD (Chemical Vapor Deposition), HDP-CVD (High-density plasma CVD), PVD (Physical Vapor Deposition), ALD (Atomic Layer Deposition) and/or spin coating. Then, the dielectric material is planarized by, for example, a CMP (Chemical-Mechanical Planarization) to expose the topmost active channel layer SH. Then, a portion of the dielectric material is removed by, for example, dry etching, wet etching, RIE (Reactive-Ion Etching) or other etching process, and the remaining portion of the dielectric material forms the oxide layers 107. The oxide layer 107 is referred to as, for example, a STI (Shallow Trench Isolation).

Then, as illustrated in FIGS. 1D_a and 1D_b, FIG. 1D_a illustrates a cross-sectional view of the structure in FIG. 1C along a direction a-a′, and FIG. 1D_b illustrates a cross-sectional view of the structure in FIG. 1C along a direction b-b′. A liner 122 over the active structures, the oxide layer 107 and the topmost active channel layer SH is formed by using, for example, deposition. In an embodiment, the liner 122 may be formed of a material including Si₃N₄, SiO₂, SiON, Si, SiGe, etc., and the liner 122 has a thickness ranging between, for example, 0.5 nm and 10 nm. In an embodiment, the liner 122 may be formed before the removal of the dummy gate structures DG. In another embodiment, the liner 122 may be formed before the formation of the oxide layer 107.

In another embodiment, before formation of the oxide layer 107 (for example, i step of FIG. 1B), the liner 122 may be formed on at least one of surfaces of the first protrusion 1051, at least one of surfaces of the second protrusion 1052 and at least one of surfaces of the active structure (for example, the first active structure FS1 and the second active structure FS2).

Then, as illustrated in FIG. 1D_b, a plurality of dummy gate structures DG is formed on the active structure for defining a region of the active region, and then a poly spacer material 130′ over the dummy gate structures DG and the active structures (for example, the first active structure FS1 and the second active structure FS2) is formed by using, for example, deposition.

In an embodiment, the dummy gate structure DG includes a dummy dielectric layer DG1, a dummy gate layer DG2, a mask layer DG3 and an oxide layer DG4. The dummy dielectric layer DG1 is formed on the active structures FS. The dummy dielectric layer DG1 is formed of a material including, for example, silicon oxide, silicon nitride, a combination thereof, or the like, and may be deposited or thermally grown according to acceptable techniques. The dummy gate layer DG2 is formed over the dummy dielectric layer DG1, and the mask layer DG3 is formed over the dummy gate layer DG2. The dummy gate layer DG2 may be deposited over the dummy dielectric layer DG1 and then planarized, such as by CMP. The mask layer DG3 may be deposited over the dummy gate layer DG2. The dummy gate layer DG2 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer DG2 may be deposited by PVD, CVD, sputter deposition, or other techniques for depositing the selected material. The dummy gate layer DG2 may be formed of other materials that have a high etching selectivity from the etching of isolation regions. The mask layer DG3 may include, for example, silicon nitride, silicon oxynitride, or the like.

In an embodiment, the poly spacer material 130′ may be formed of a material including, for example, SiO, SiN, SiOC, SiON, SiOCN, etc. The poly spacer material 130′ may be single-layered structure or a multi-layered structure. For multi-layered structure, the poly spacer material 130′ may include a first-sub spacer portion 131 and a second-sub spacer portion 132, wherein the second-sub spacer portion 132 is disposed between the dummy gate structures DG and the first-sub spacer portion 131. The first-sub spacer portion 131 is formed of a material different from that of the second-sub spacer portion 132.

Then, as illustrated in FIGS. 1E_a and 1E_b, a portion of the active structure which is not covered by the dummy gate structure DG is removed to form a plurality of source/drain trenches T1, and a portion of the poly spacer material 130′ is removed by etching such as dry etching, wet etching, RIE or other suitable etching process. The source/drain trenches T1 may divide the first active structure FS1 into a plurality of active regions FS11 including a plurality of the first active channels 110 and a plurality of interposers 117. Although not illustrated, the source/drain trenches T1 may divide the second active structure FS2 into a plurality of active regions including a plurality of the second active channels 120 and a plurality of the interposers 117. In addition, the etching process may use bromine-containing etchants (HBr and/or CHBr₃), fluorine-containing etchants (CF₄, SF₆, CH₂F₂, CHF₃ and/or C₂F₆) or other suitable etchant. After etching, the remaining portion of the poly spacer material 130′ forms a plurality of the poly spacers 130 including the first-sub spacer portion 131 and the second-sub spacer portion 132, and the poly spacers 130 are disposed on and above the liner 122, and the poly spacer 130 are disposed on sidewalls of the dummy gate structure DG. In an embodiment, the active channel is, for example, nanosheet.

Then, as illustrated in FIGS. 1F_a and 1F_b, two recesses 117r are formed in adjacent two ends of the interposer 117 by using, for example, wet etching. The wet etching may selectively etches the interposers 117, and the wet etchant includes, but not limited to, ammonium hydroxide (NH₄OH), tetramethylammonium hydroxide (TMAH), ethylenediamine ptrocatechol (EDP) and potassium hydroxide (KOH).

Then, as illustrated in FIGS. 1G_a and 1G_b, a plurality of the inner spacers 124 are formed in the recesses 117r.

In a process of the inner spacer 124, an inner spacer material over the poly spacers 130, the active channel 110, the recesses 117r, and sidewalls of the source/drain trenches T1 is formed by using, for example, deposition. The inner spacer material is formed of a material including silicon oxide, silicon nitride, silicon carbide, silicon carbon nitride, silicon carbon nitride, silicon carbon oxynitride or other suitable material. Then, a portion of the inner spacer material is removed by using, for example, ALD, etc. The remaining portion of the inner spacer material forms a plurality of the inner spacers 124.

Then, as illustrated in FIGS. 1H_a and 1H_b, the separation layers 108 may be formed on a bottom of the source/drain trenches T1. In an embodiment, the separation layer 108 may be a semiconductor layer, for example, undoped silicon layer, silicon layer, silicon germanium layer, and the separation layers 108 may be formed by MBE, CVD, MOCVD, etc. Then, the isolation layer 125 over the separation layer 108 is formed by using, for example, deposition, photolithography, etc. Then, a plurality of the source/drain layers 150 over the isolation layer 125 may be formed within the source/drain trenches T1.

In an embodiment, the source/drain layer 150 may be formed using an epitaxial process, such as VPE, UHV-CVD, MBE, and/or other suitable processes. Example n-type source/drain layer may include Si, GaAs, GaAsP, SiP, or other suitable material and may be in-situ doped during the epitaxial process by introducing an n-type dopant, such as phosphorus (P), arsenic (As), or ex-situ doped using an implantation process (i.e., a junction implant process). Example p-type source/drain layer may include Si, Ge, AlGaAs, SiGe, boron-doped SiGe, or other suitable material and may be in-situ doped during the epitaxial process by introducing a p-type dopant, or ex-situ doped using an implantation process (i.e., a junction implant process). In an embodiment, one of the source/drain layer 150 may be used as a source region of a transistor, another of the source/drain layer 150 may be used as a drain region of the transistor, and the active channels located between the source region and the drain region may be used as a gate region of the transistor.

Then, as illustrated in FIGS. 1I_a and 1I_b, a CESL (Contact Etch Stop Layer) material 155′ over the poly spacers 130, the source/drain layers 150 and upper surfaces of the dummy gate structures DG are formed by using, for example, deposition, such as chemical vapor deposition (CVD), Plasma-Enhanced Chemical Vapor Deposition (PECVD), ALD (atomic layer deposition), or the like. The CESL material 155′ may be formed of a material including, for example, a dielectric material, such as silicon nitride, silicon oxide, silicon oxynitride, or the like. Then, the ILD 170 covering the CESL material 155′ and the liner 122 is formed by using, for example, deposition, such as CVD, PECVD, or flowable chemical vapor deposition (FCVD), or the like. The ILD 170 may be formed of a dielectric including, for example, PSG, BSG, boron-doped phospho-silicate glass (BPSG), undoped silicate glass (USG), or the like. Other insulation materials formed by any acceptable process may be used.

Then, as illustrated in FIGS. 1J_a and 1J_b, the ILD 170, the CESL material 155′ and the dummy gate structures DG may be planarized by using, for example, Chemical-Mechanical Polishing (CMP). After being planarized, the CESL material 155′ forms a plurality of the CESLs 155, and the mask layer DG3 and the oxide layer DG4 of the dummy gate structure DG may be removed, and the dummy dielectric layer DG1 and the dummy gate layer DG2 may be retained. In addition, after being planarized, the dummy gate layer DG, the poly spacer 130 and the ILD 170 may form, for example, a planarized surface.

Then, as illustrated in FIG. 1K_b, the dummy dielectric layer DG1 and the dummy gate layer DG2 on FIG. 1J_b may be removed by using, for example, etching. After the dummy dielectric layer DG1 and the dummy gate layer DG are removed, the liner 122 is exposed.

Then, as illustrated in FIGS. 1K_a and 1K_c, FIG. 1K_c illustrates a cross-sectional view of the structure in FIG. 1K_a along a direction c-c′ (the direction c-c′ is illustrated in FIG. 1C). A block layer 133 over a portion 122A of the liner 122 which covers the second active structure FS2 (which includes the second active channels 120) is formed by using, for example, deposition, photolithography, etching, etc. The block layer 133 is formed of a material including, for example, SOC, SOG, SiOC, SiOCN, SiO₂, Al₂O₃, photoresist, etc. In an embodiment, the block layer 133 is, for example, a bottom anti-reflective coating (BARC).

Then, as illustrated in FIGS. 1L_a and 1L_b, a portion 122B1 of the liner 122 which is not covered by the block layer 133 is removed by using, for example, dry etching, or a combination of implanting and wet etching. The wet etching is performed in an atmosphere of HF-, NH4OH-, HCl-, H2SO4-based. After etching, the topmost first active channel 110A is exposed. The topmost first active channel 110A includes a first portion 110A1 and a second portion 110A2, wherein the first portion 110A1 and the poly spacer 130 overlap in Z-axis, and the second portion 110A2 does not overlap the poly spacer 130 in Z-axis. A portion 122B2 of the liner 122 is remained between the poly spacer 130 and the first portion 110A1 of the first active channel 110A. As illustrated in FIGS. 1L_a and 1L_c, due to the block layer 133 covering the portion 122A of the liner 122 which covers the topmost second active channel 120, the portion 122A of the liner 122 covering the topmost second active channel 120 is not removed.

Then, as illustrated in FIGS. 1M_a to 1M_c, the block layer 133 in FIG. 1L_a is removed by using, for example, striping. The striping technique is, for example, dry etching, wet etching, etc. The dry etching is performed in an atmosphere of N₂/O₂, N₂/H₂, etc., and the wet etching is performed in an atmosphere of H₂O₄-, O₃-based, etc. After removal, the portion 122A of the liner 122 is exposed.

Then, as illustrated in FIGS. 1N_a a to 1N_c, the exposed topmost first active channel 110A in FIG. 1M_a which is not covered by the liner 122 is removed by using, for example, dry etching, wet etching, etc. As illustrated in FIG. 1N_b, after removal, the exposed second portion 110A2 of the topmost first active channel 110A is removed, but the covered first portion 110A1 (the semiconductor portion and/or the remaining portion of the topmost first active channel 110A) of the topmost first active channel 110A is retained. As a result, the number of the first active channels 110 of the first active structure FS1 is reduced by one. The first portion 110A1 (the semiconductor portion) is formed of a material the same as that of the first active channel 110. The first portion 110A1 forms a recess 110A1r recessed relative to a lateral surface 110A1s of the first portion 110A1 due to the etching. As illustrated in FIG. 1N_c, due to the topmost second active channel 120 being covered by the portion 122A of the liner 122, the topmost second active channel 120 is not removed, and thus the number of the second active channels 120 of the second active structure FS2 may be maintained.

Then, as illustrated in FIGS. 1O_a and 1O_b, the liner 122 is removed by using, for example, dry etching, wet etching, etc. As illustrated in FIG. 1O_c, a portion 122A1 of the liner 122 is removed by using, for example, dry etching, wet etching, etc. After etching, the topmost second active channel 120 is exposed. A portion 122A2 of the liner 122 between the poly spacer 130 and the topmost second active channel 120 is remained. Then, as illustrated in FIGS. 1O_b and 1O_c, the interposers 117 are removed by using, for example, dry etching, wet etching, etc. After the interposers 117 are removed, the active channels (for example, the first active channels 110 and the second active channels 120) are exposed.

Then, as illustrated in FIGS. 1P_a to 1P_c, the interfacial layers (ILs) 135 are formed in or on the exposed first active channels 110 and the exposed second active channels 120 by using, for example, deposition. In an embodiment, the interfacial layer 135 is formed a material including, for example, SiO₂, SiON, HfSiOx, LaSiOx, YSiOx, AlSiOx, etc., and the interfacial layer 135 has a thickness ranging 0.2 nm and 2 nm. The interfacial layer 135 may be deposited by any appropriate method, such as ALD, CVD, and/or PVD. Due to the recess 110A1r of the first portion 110A1 of the topmost first active channel 110A, the interfacial layer 135 complies with a shape of the recess 110A1r to form a recess 135r.

Then, as illustrated in FIGS. 1P_a and 1P_b, a gate dielectric layer 140 over the inner spacers 120, the poly spacers 130 and the interfacial layers 135 is formed. The gate dielectric layer 140 may be formed in the same process, for example, deposition, such as ALD, CVD, metal-organic CVD, PVD or a combination thereof. Similarly, due to the recess 135r of the interfacial layer 135, the gate dielectric layer 140 complies with a shape of the recess 135r to form a recess 140r. However, depending on the depth of the recess 110A1r, the recess 135r and/or the recess 140r may be may be absent or inconspicuous.

The gate dielectric layer 140 may be formed of a material including: (i) a high-k (HK) dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), zirconium silicate (ZrSiO₂), La₂O₃, Al₂O₃, HfZrOx, HfLaOx, HfAlOx, HfYOx, HfSiOx or HfSiON; and (ii) a high-k dielectric material having oxides of lithium (Li), beryllium (Be), magnesium (Mg), calcium (Ca), strontium (Sr), scandium (Sc), yttrium (Y), zirconium (Zr), aluminum (Al), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), (iii) other suitable high-k dielectric materials, or (iv) a combination thereof. As used herein, the term “high-k” refers to a high dielectric constant. In the field of semiconductor structure structures and manufacturing processes, high-k refers to a dielectric constant that is greater than the dielectric constant of SiO₂ (e.g., greater than 3.9).

Then, as illustrated in FIGS. 1P_a and 1P_b, a metal gate 115 over the gate dielectric layers 140 is formed by a process such as ALD, CVD, PVD, remote plasma CVD (RPCVD), plasma enhanced CVD (PECVD), metal-organic CVD (MOCVD), sputtering, electroplating, other suitable processes, or the like. By way of example, the metal gate 115 may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. Further, the metal gate 115 may be formed separately for n-type transistors and p-type transistors, which may use different metal layers (e.g., for providing different n-type and p-type work function metal layers). Then, the metal gates 115, the poly spacers 130 and the gate dielectric layers 140 may be planarized by, for example, CMP.

Then, as illustrated in FIGS. 1Q_b and 1Q_c, a hole 170a extending to the source/drain layer 150 is formed in the ILD 170 in FIGS. 1P_b and 1P_c by using, for example, photolithography, etching, etc. Then, the silicide layers 145 in or on the exposed source/drain layers 150 are formed by using, for example, deposition. The silicide layer 145 may be a metal or metal alloy silicide, and the metal includes a noble metal, a refractory metal, a rare earth metal, alloys thereof, or combinations thereof. For n-channel FET, the silicide layer 145 may include one or more of TiSi, CrSi, TaSi, MoSi, ZrSi, HfSi, ScSi, Ysi, HoSi, TbSI, GdSi, LuSi, DySi, ErSi, Yb Si or a combination thereof. For p-channel FET, the silicide layer 145 may include one or more of NiSi, CoSi, MnSi, Wsi, Fe Si, RhSi, PdSi, RuSi, PtSi, IrSi, OsSi or a combination thereof.

Then, as illustrated in FIGS. 1Q_a and 1Q_b, the contacts 160 in FIGS. 1P_b and 1P_c are formed over the silicide layer 145 to form at least one semiconductor structure 100. The contacts 160 may be formed of a metal including Ru, Mo, Co, Ni, W, Ti, Ta, Cu, Al, TiN, TaN or a combination thereof. The contact 160 may be formed by any suitable process, such as PVD, CVD, ALD, electroplating, or other suitable methods.

As illustrated in FIGS. 1Q_a and 1Q_b, the first active channels 110 are disposed on the substrate 105 and vertically stacked to each other. The second active channels 120 are disposed on the substrate 105 vertically stacked to each other. The number of the first active channels 110 and the number of the second active channels 120 are different. For example, the number of the first active channels 110 is two, and the number of the second active channels 120 three. In another embodiment, the number of the first active channels 110 is N while the number of the second active channels 120 N+n, wherein the value of N is positive number equal to or greater than 1, and the value of n is positive number equal to or greater than 1. In another embodiment, the number of the first active channels 110 is N while the number of the second active channels 120 is N−n, wherein the value of N is positive number equal to or greater than 2, and the value of n is positive number equal to or greater than 1. In the present embodiment, the whole of the first active channels 110 and the whole of the second active channels 120 are disposed adjacently. The less the number of the active channels is, the less the channel capacitance is, the less the power consumption is, and the less the current leakage is.

In an embodiment, to increase design flexible and functionality for nano-sheet device, a hybrid sheet approach to make the different sheet number between N-FET (field-effect transistor) and P-FET intra cell is proposed. Moreover, various sheet number in specific cell may also provide more functionality for nano-sheet devices. For example, the hybrid sheet may offer 2-sheets for low power and low leakage optimization, and 3-sheets for high performance computing in the same chip (cell level). The capacitance of channel (Cgc) may be reduced by lack of one sheet. Therefore, the effective capacitance (Ceff) may be decreased to lead to power efficiency improvement by hybrid sheet approach. In addition, the current leakage may be reduced on 2-sheet cell due to less channel area than 3-sheet cell.

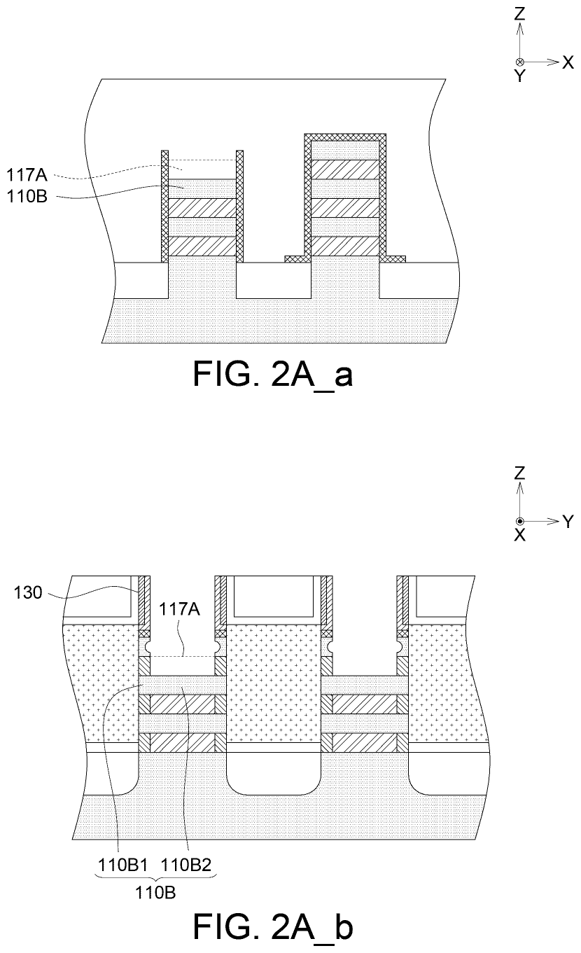

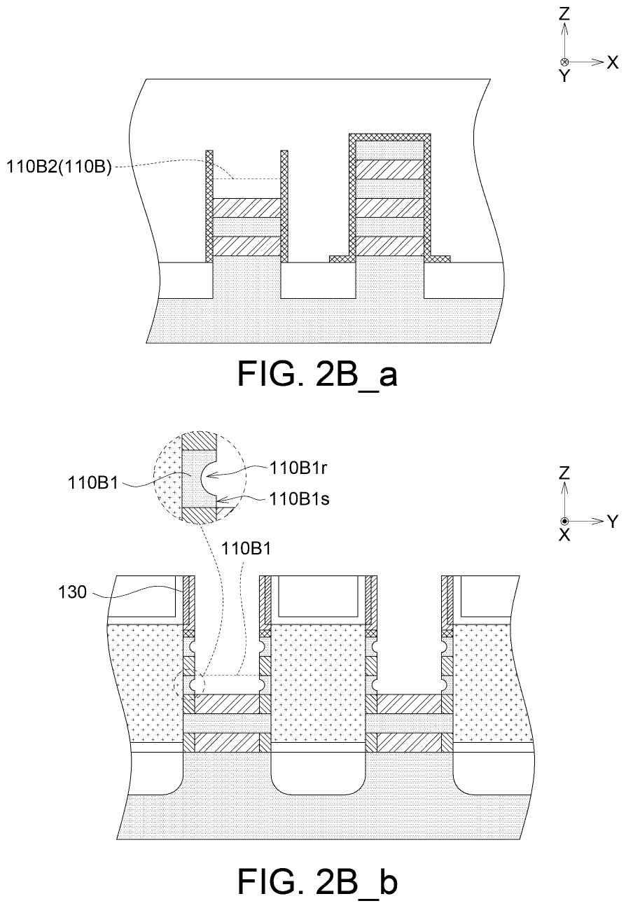

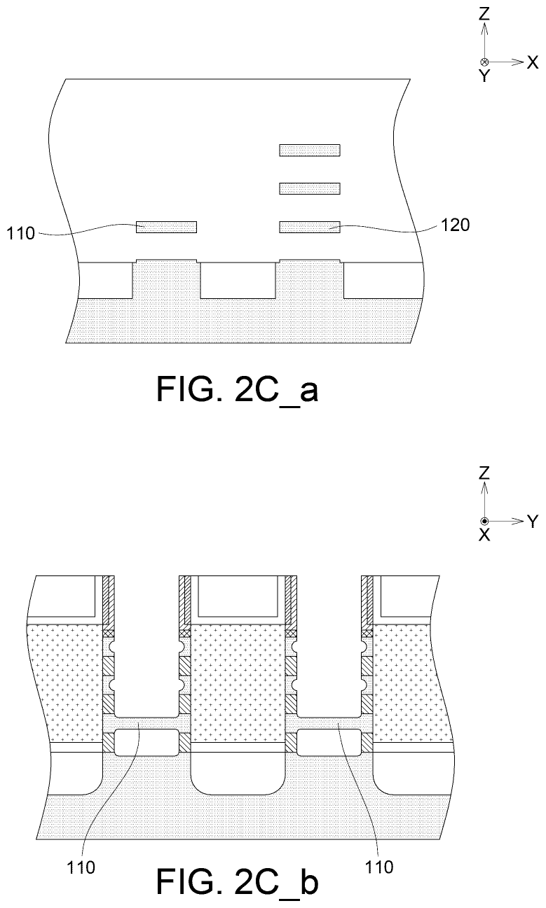

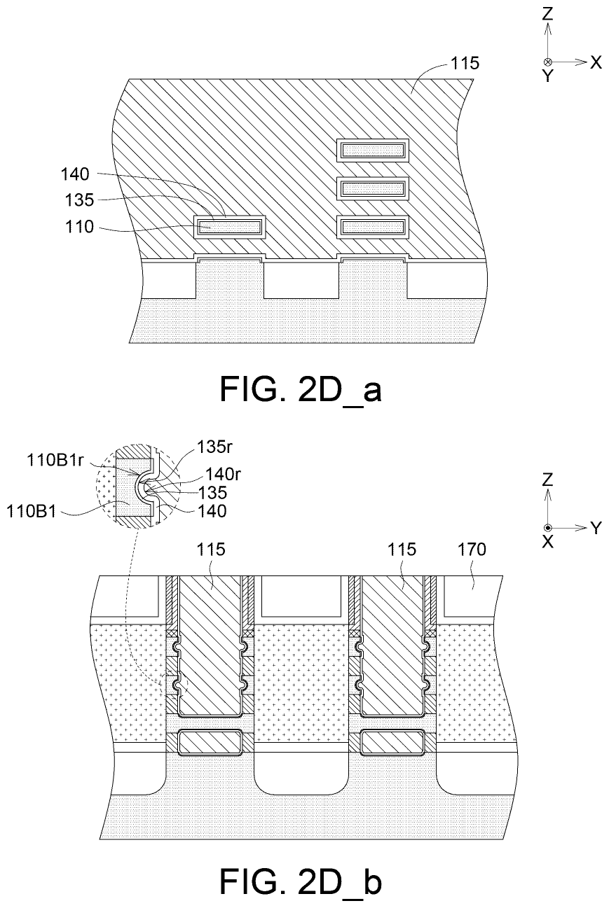

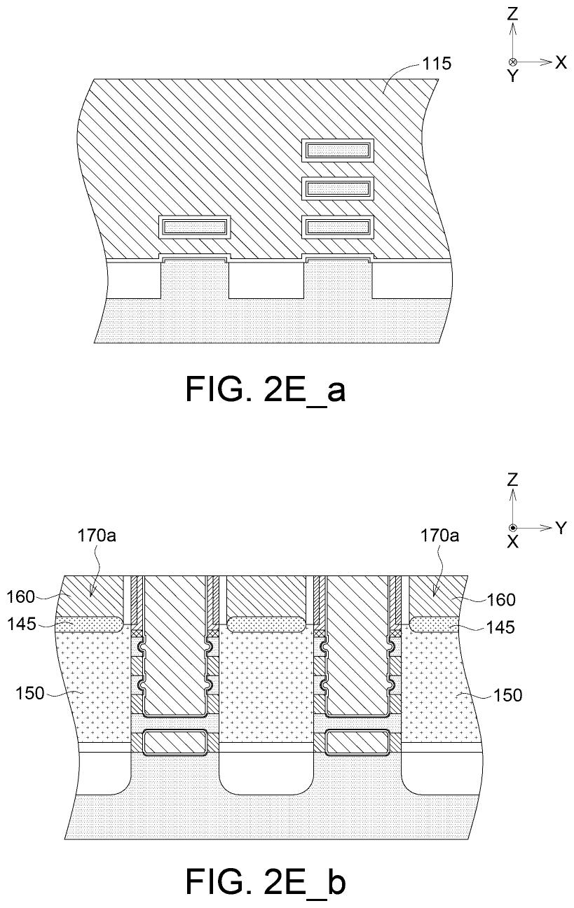

FIGS. 2A_a to 2E_b illustrate schematic diagrams of manufacturing processes of a semiconductor structure 200 according to another embodiment of the present disclosure. The manufacturing processes of the semiconductor structure 200 include the steps the same as or similar to that of the manufacturing processes (for example, corresponding to FIGS. 1A to 1N_c) of the semiconductor structure 100, and only the differences will be explained below.

As illustrated in FIGS. 2A_a and 2A_b, after the topmost first active channel 110A in FIG. 1N_a is removed, the topmost interposer 117A which is not covered by the liner 122 is exposed. The topmost interposer 117A is removed by using, for example, dry etching, wet etching, etc. As illustrated in FIG. 2A_b, the exposed topmost interposer 117A is removed. The topmost first active channel 110B in FIG. 2A_b includes a first portion 110B1 and a second portion 110B2, wherein the first portion 110B1 and the poly spacer 130 overlap in Z-axis, and the second portion 110B2 does not overlap the poly spacer 130 in Z-axis.

As illustrated in FIGS. 2B_a and 2B_b, the exposed topmost first active channel 110B in FIGS. 2A_a and 2A_b which is not covered by the liner 122 is removed by using, for example, dry etching, wet etching, etc. As illustrated in FIG. 2B_b, the exposed second portion 110B2 of the topmost first active channel 110B is removed, and the covered first portion 110B1 of the topmost first active channel 110B is retained. The first portion 110B1 forms a recess 110B1r recessed relative to a lateral surface 110B1s of the first portion 110B1 due to the etching.

As illustrated in FIGS. 2C_a and 2C_b, the liner 122 in FIGS. 2B_a and 2B_b is removed by using, for example, dry etching, wet etching, etc. Then, the interposers 117 in FIGS. 2B_a and 2B_b are removed by using, for example, dry etching, wet etching, etc. After the interposers 117 are removed, the active channels are exposed.

As illustrated in FIGS. 2D_a and 2D_b, the interfacial layers 135 are formed in or on the exposed first active channels 110 and the exposed second active channels 120 by using, for example, deposition. In an embodiment, the interfacial layer 135 is formed a material including, for example, SiO₂, SiON, HfSiOx, LaSiOx, YSiOx, AlSiOx, etc., and the interfacial layer 135 has a thickness ranging 0.2 nm and 2 nm. The interfacial layer 135 may be deposited by any appropriate method, such as ALD, CVD, and/or PVD.

Then, as illustrated in FIGS. 2D_a and 2D_b, the gate dielectric layer 140 over the inner spacers 120, the poly spacers 130 and the interfacial layers 135 is formed. The gate dielectric layer 140 may be formed in the same process, for example, deposition, such as ALD, CVD, metal-organic CVD, PVD or a combination thereof. Similarly, due to the recess 135r of the interfacial layer 135, the gate dielectric layer 140 complies with a shape of the recess 135r to form the recess 140r. However, depending on the depth of the recess 110B1r, the recess 135r and/or the recess 140r may be may be absent or inconspicuous.

Then, as illustrated in FIGS. 2D_a and 2D_b, the metal gate 115 over the gate dielectric layers 140 is formed by a process such as ALD, CVD, PVD, remote plasma CVD (RPCVD), plasma enhanced CVD (PECVD), metal-organic CVD (MOCVD), sputtering, electroplating, other suitable processes, or the like. Further, the metal gate 115 may be formed separately for n-type transistors and p-type transistors, which may use different metal layers (e.g., for providing different n-type and p-type work function metal layers). Then, the metal gates 115, the poly spacers 130 and the gate dielectric layers 140 may be planarized by, for example, CMP.

Then, as illustrated in FIGS. 2E_a and 2E_b, the hole 170a extending to the source/drain layer 150 is formed in the ILD 170 in FIG. 2D_b by using, for example, photolithography, etching, etc. Then, the silicide layers 145 in or on the exposed source/drain layers 150 are formed by using, for example, deposition. The silicide layer 145 may be a metal or metal alloy silicide, and the metal includes a noble metal, a refractory metal, a rare earth metal, alloys thereof, or combinations thereof. For n-channel FET, the silicide layer 145 may include one or more of TiSi, CrSi, TaSi, MoSi, ZrSi, HfSi, ScSi, Ysi, HoSi, TbSI, GdSi, LuSi, DySi, ErSi, Yb Si or a combination thereof. For p-channel FET, the silicide layer 145 may include one or more of NiSi, CoSi, MnSi, Wsi, Fe Si, RhSi, PdSi, RuSi, PtSi, IrSi, OsSi or a combination thereof.

Then, as illustrated in FIGS. 2E_a and 2E_b, the contacts 160 in FIG. 2D_b are formed over the silicide layer 145 in FIG. 2D_b to form at least one semiconductor structure 200. The contacts 160 may be formed of a metal including Ru, Mo, Co, Ni, W, Ti, Ta, Cu, Al, TiN, TaN or a combination thereof. The contact 160 may be formed by any suitable process, such as PVD, CVD, ALD, electroplating, or other suitable methods.

As illustrated in FIGS. 2E_a and 2E_b, compared to the number of the second active channels 120 of the second active structure FS2, the number of the first active channels 110A of the first active structure FS1 is reduced by two.

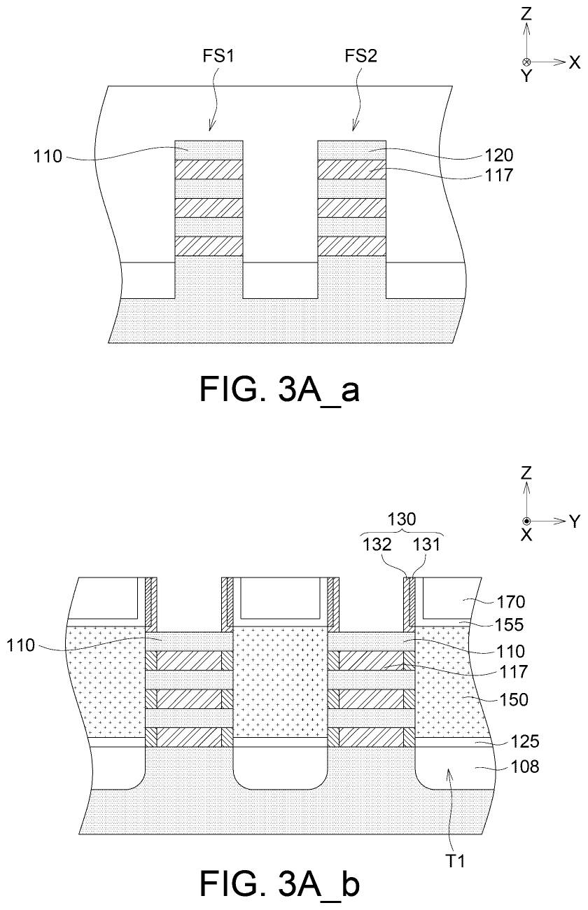

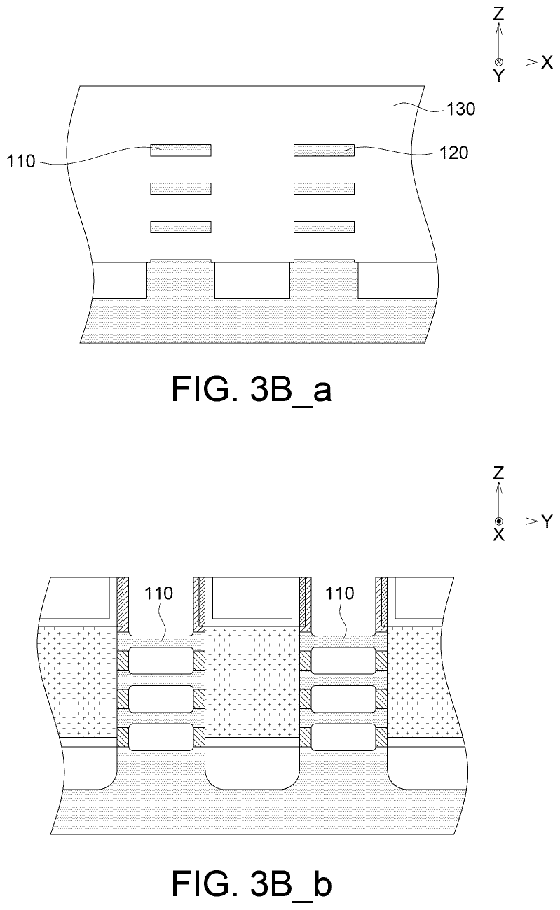

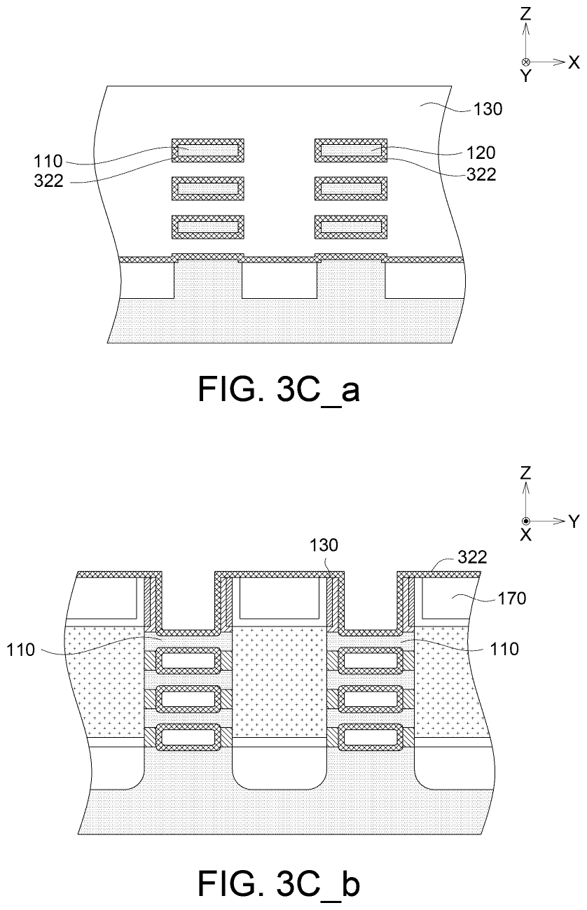

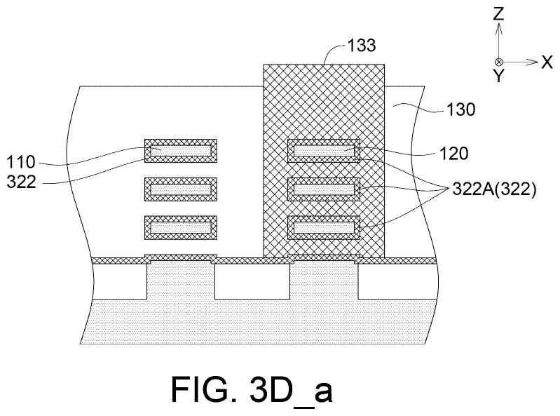

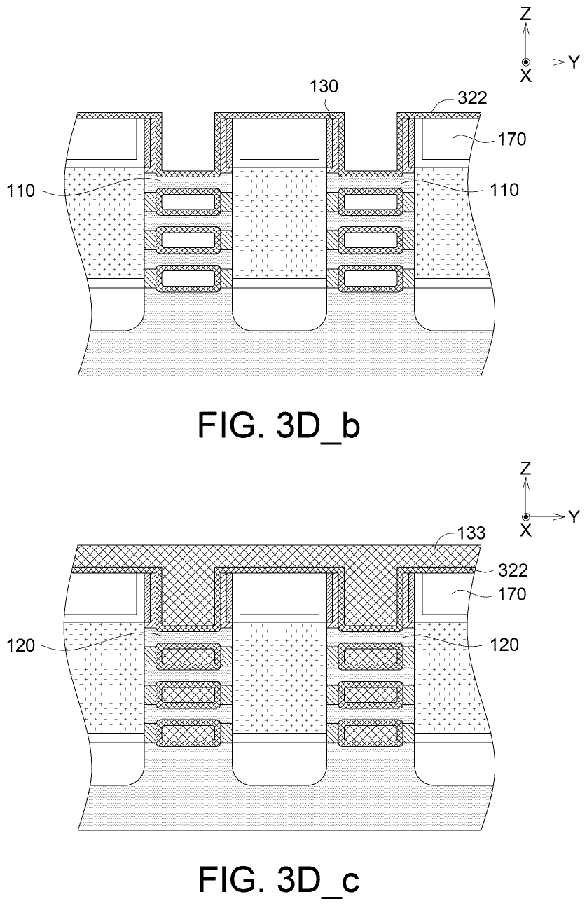

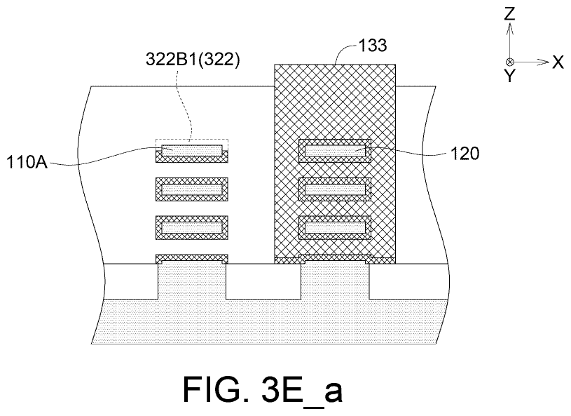

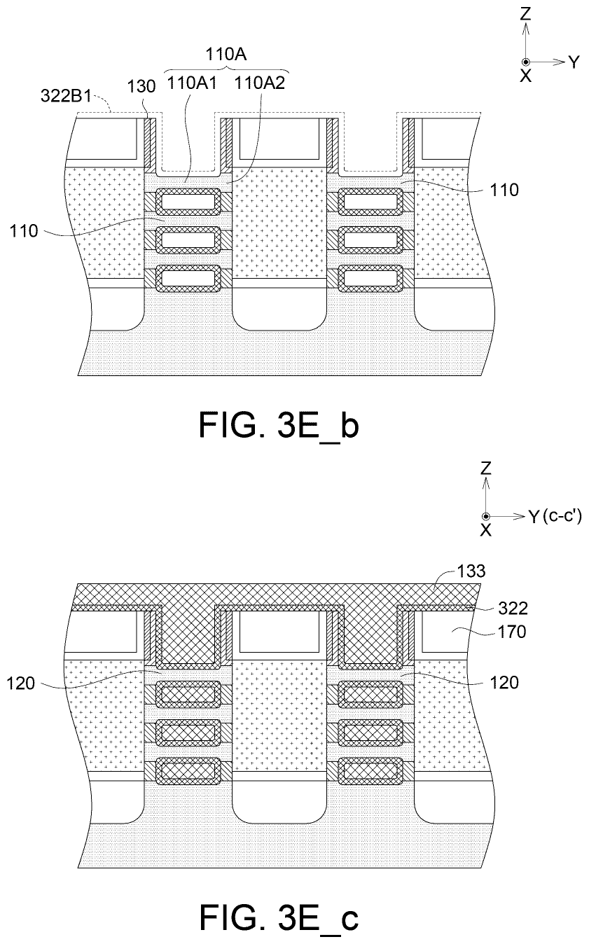

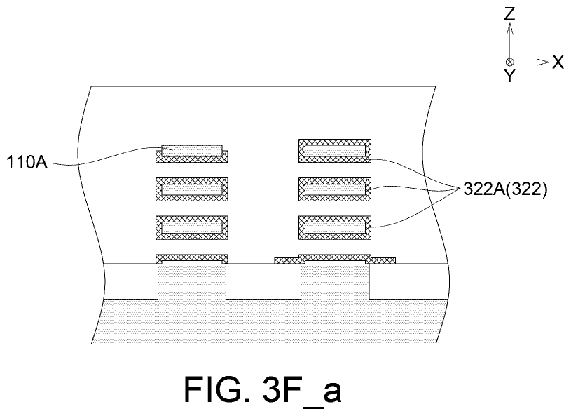

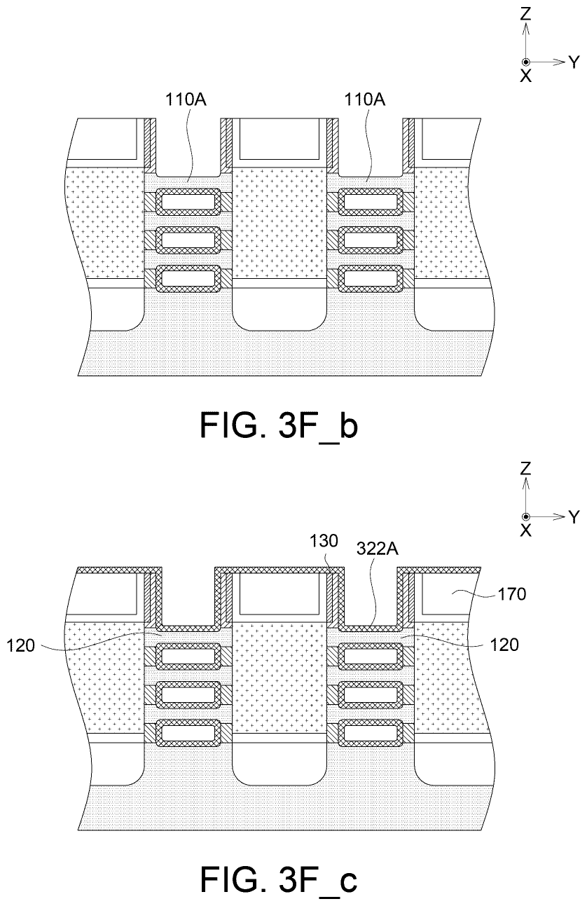

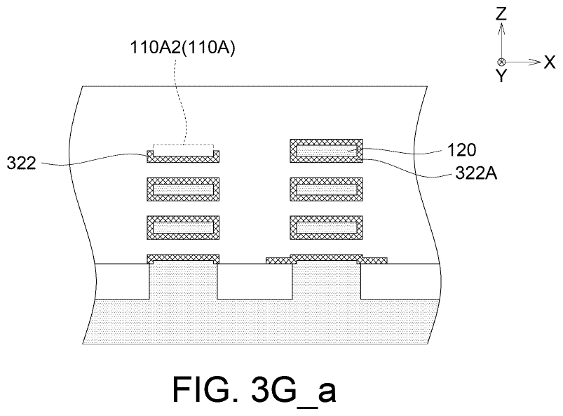

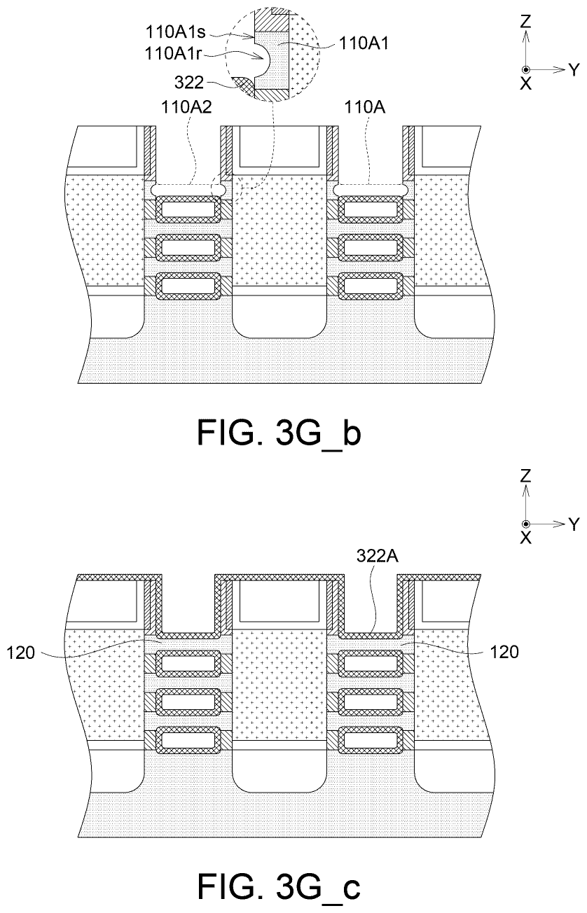

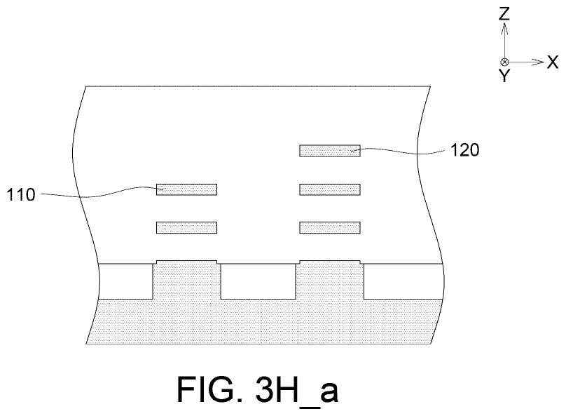

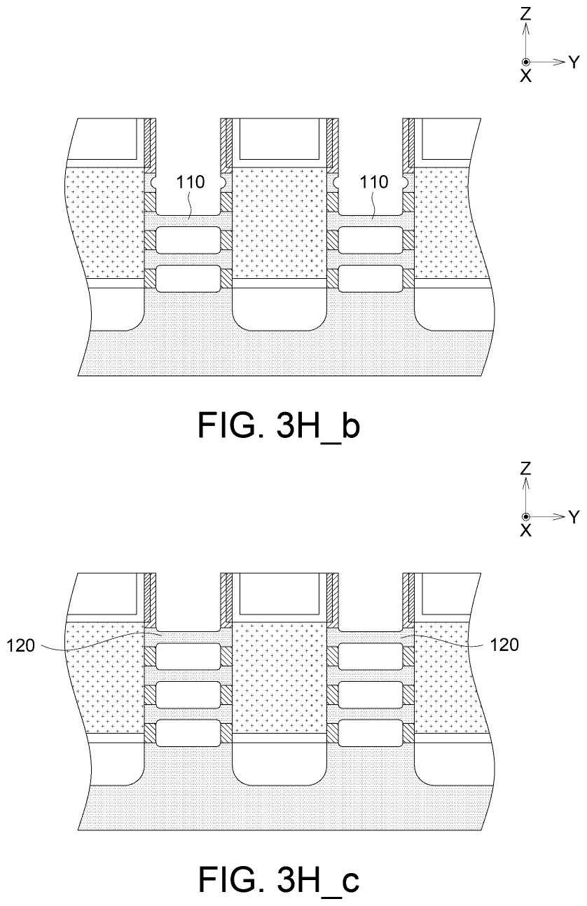

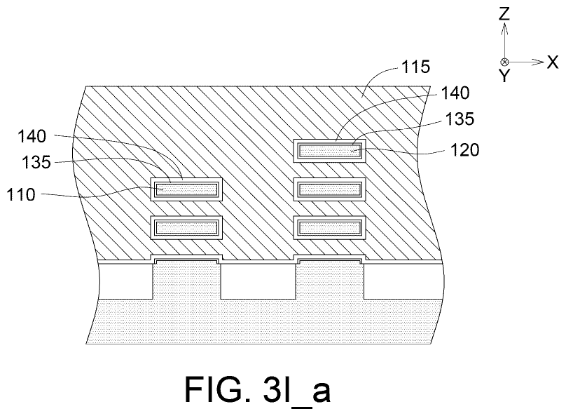

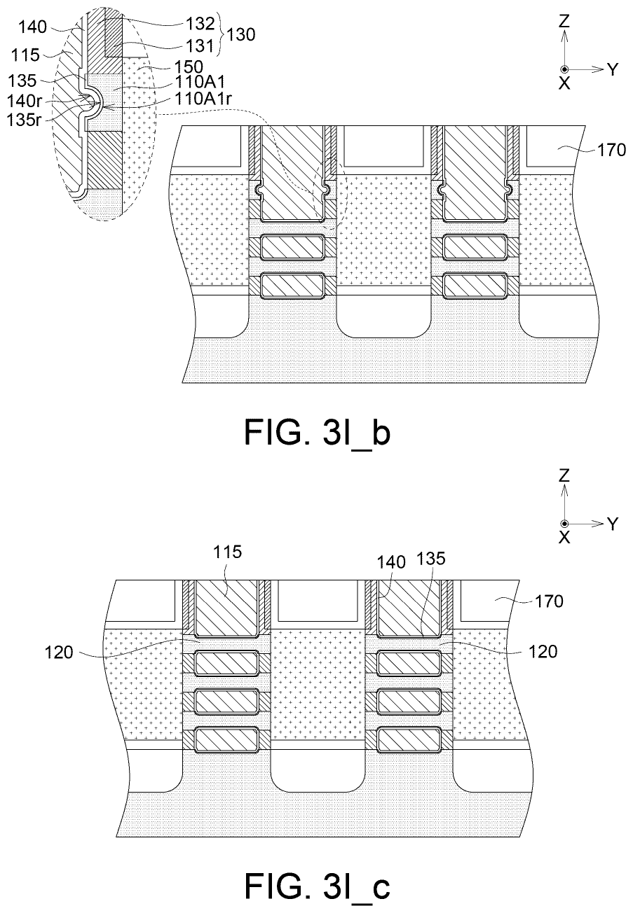

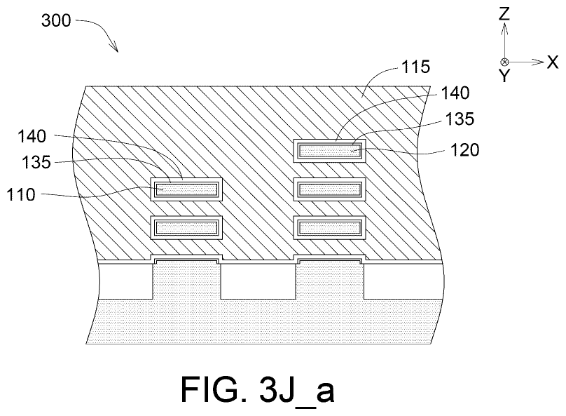

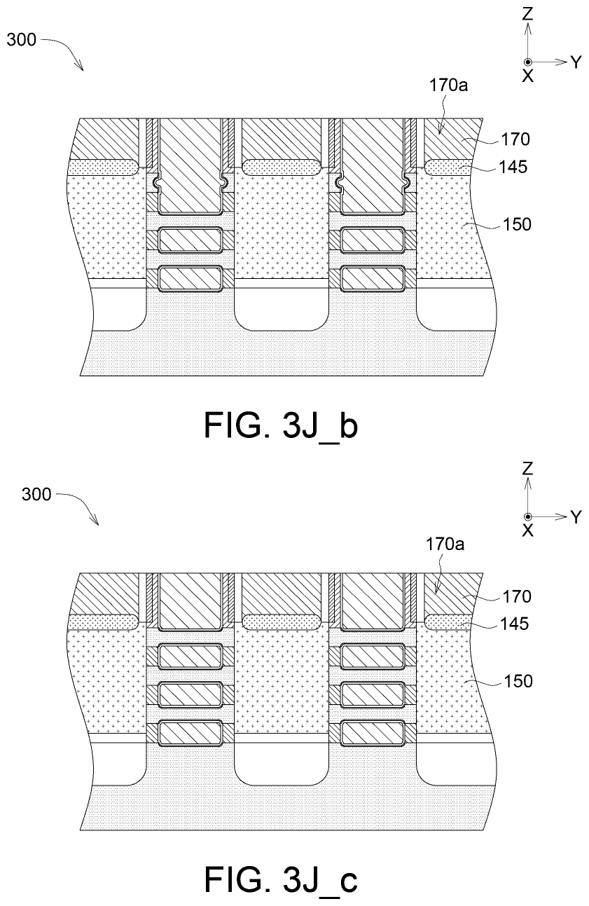

FIGS. 3A_a to 3J_c illustrate schematic diagrams of manufacturing processes of a semiconductor structure 300 according to another embodiment of the present disclosure.

As illustrated in FIGS. 3A_a and 3A_b, a plurality of active structures (for example, the first active structure FS1 and the second active structure FS2) is formed. The first active structure FS1 includes a plurality of the first active channels 110 and a plurality of the interposers 117, wherein the two adjacent first active channels 110 are spaced by one interposer 117, or the two adjacent interposers 117 are spaced by one first active channel 110. The second active structure FS2 includes a plurality of the second active channels 120 and a plurality of the interposers 117, wherein the two adjacent second active channels 120 are spaced by one interposer 117, or the two adjacent interposers 117 are spaced by one second active channel 120.

The separation layer 108 is formed on a bottom of the source/drain trenches T1 by MBE, CVD, MOCVD, etc. The isolation layer 125 over the separation layer 108 is formed by using, for example, deposition, photolithography, etc. The CESL 150 over the poly spacers 130 and the source/drain layers 150 may be formed by using, for example, deposition, such as chemical vapor deposition (CVD), Plasma-Enhanced Chemical Vapor Deposition (PECVD), ALD (atomic layer deposition), or the like. The CESL material 155′ may be formed of a material including, for example, a dielectric material, such as silicon nitride, silicon oxide, silicon oxynitride, or the like. The ILD 170 covering the CESL 155 is formed by using, for example, deposition, such as CVD, PECVD, or flowable chemical vapor deposition (FCVD), or the like. The dummy gate structures DG (for example, the dummy dielectric layer DG1 and the dummy gate layer DG2) in FIG. 1J_b are removed to expose the active channels (for example, the topmost first active channel 110 and the topmost second active channel 120) by using, for example, etching.

The structure of FIG. 3A_a is similar to that of FIGS. 1K_a to 1K_c, and the difference is that the structure in FIG. 3A_a may omit the liner 122 and the block layer 133. Different from the manufacturing processes of the semiconductor structures 100 and 200, the manufacturing processes of the semiconductor structure 300 do not include the step of forming the liner 122 in FIGS. 1D_a and 1D_b.

Then, as illustrated in FIGS. 3B_a and 3B_b, the interposers 117 in FIGS. 3A_a and 3A_b are removed by using, for example, dry etching, wet etching, etc. After the interposers 117 are removed, the active channels (for example, the first active channels 110 and the second active channels 120) are exposed. In an embodiment, the aforementioned dummy gate structures DG and the interposers 117 may be removed in the same removal process.

Then, as illustrated in FIGS. 3C_a and 3C_b, a liner 322 encapsulating the active channels (for example, the first active channels 110 and the second active channels 120) is formed by using, for example, deposition, such as ALD or CVD. The liner 322 may be formed a material including, for example, Al₂O₃, HfO₂, SiO₂, Si₃N₄, etc. The liner 322 has a thickness ranging between, for example, 0.5 nm and 5 nm.

Then, as illustrated in FIGS. 3D_a and 3D_c, the block layer 133 over a portion 322A of the liner 322 which encapsulate the second active channels 120 is formed by using, for example, deposition, photolithography, etching, etc.

Then, as illustrated in FIGS. 3E_a and 3E_b, a portion 322B1 of the liner 322 which is disposed above the topmost first active channels 110A and is not covered by the block layer 133 is removed by using, for example, dry etching, or a combination of implanting and wet etching. The wet etching is performed in an atmosphere of HF-, NH4OH-, HCl-, H2SO4-based. After etching, the topmost first active channel 110A is exposed. The topmost first active channel 110A includes the first portion 110A1 and the second portion 110A2, wherein the first portion 110A1 and the poly spacer 130 overlap in Z-axis, and the second portion 110A2 does not overlap the poly spacer 130 in Z-axis. As illustrated in FIGS. 3E_a and 3E_c, due to the block layer 133 covering the portion 322A of the liner 322 which encapsulates the second active channels 120 is not removed.

Then, as illustrated in FIGS. 3F_a to 3F_c, the block layer 133 in FIG. 3E_a is removed by using, for example, striping. The striping technique is, for example, dry etching, wet etching, etc. The dry etching is performed in an atmosphere of N₂/O₂, N₂/H₂, etc., and the wet etching is performed in an atmosphere of H₂O₄-, O₃-based, etc. After removal, the portion 322A of the liner 322 is exposed.

Then, as illustrated in FIGS. 3G_a to 3G_c, the exposed topmost first active channel 110A in FIGS. 3F_a and 3F_b which is not covered by the liner 322 is removed by using, for example, dry etching, wet etching, etc. As illustrated in FIGS. 3G_a and 3G_b, after removal, the exposed second portion 110A2 of the topmost first active channel 110A is removed, but the covered first portion 110A1 of the topmost first active channel 110A is retained. As a result, the number of the first active channels 110 is reduced by one. The first portion 110A1 forms the recess 110A1r recessed relative to the lateral surface 110A1s of the first portion 110A1 due to the etching. As illustrated in FIGS. 3G_a and 3G_c, due to the topmost second active channel 120 being covered by the portion 322A of the liner 322, the topmost second active channel 120 is not removed, and thus the number of the second active channels 120 of the second active structure FS2 may be maintained.

Then, as illustrated in FIGS. 3H_a to 3H_c, the liner 322 in FIGS. 3G_a to 3G_c is removed by using, for example, dry etching, wet etching, etc. After removal, all active channels (110 and 120) are exposed. In an embodiment, there is no residual material of the liner 322 of the structures in FIGS. 3H_a to 3H_c.

Then, as illustrated in FIGS. 3I_a to 3I_c, the interfacial layers 135 are formed or on the exposed first active channels 110 and the exposed second active channels 120 by using, for example, deposition. In an embodiment, the interfacial layer 135 is formed a material including, for example, SiO₂, SiON, HfSiOx, LaSiOx, YSiOx, AlSiOx, etc., and the interfacial layer 135 has a thickness ranging 0.2 nm and 2 nm. The interfacial layer 135 may be deposited by any appropriate method, such as ALD, CVD, and/or PVD. Due to the recess 110A1r of the first portion 110A1 of the topmost first active channel 110A, the interfacial layer 135 complies with a shape of the recess 110A1r to form the recess 135r.

Then, as illustrated in FIGS. 3I_a and 3I_b, the gate dielectric layer 140 over the inner spacers 120, the poly spacers 130 and the interfacial layers 135 is formed. The gate dielectric layer 140 may be formed in the same process, for example, deposition, such as ALD, CVD, metal-organic CVD, PVD or a combination thereof. Similarly, due to the recess 135r of the interfacial layer 135, the gate dielectric layer 140 complies with a shape of the recess 135r to form the recess 140r. However, depending on the depth of the recess 110A1r, the recess 135r and/or the recess 140r may be may be absent or inconspicuous.

Then, as illustrated in FIGS. 3J_a and 3J_b, a hole 170a extending to the source/drain layer 150 is formed in the ILD 170 in FIG. 3I_b by using, for example, photolithography, etching, etc. Then, the silicide layers 145 in or on the exposed source/drain layers 150 are formed by using, for example, deposition. The silicide layer 145 may be a metal or metal alloy silicide, and the metal includes a noble metal, a refractory metal, a rare earth metal, alloys thereof, or combinations thereof. For n-channel FET, the silicide layer 145 may include one or more of TiSi, CrSi, TaSi, MoSi, ZrSi, HfSi, ScSi, Ysi, HoSi, TbSI, GdSi, LuSi, DySi, ErSi, Yb Si or a combination thereof. For p-channel FET, the silicide layer 145 may include one or more of NiSi, CoSi, MnSi, Wsi, Fe Si, RhSi, PdSi, RuSi, PtSi, IrSi, OsSi or a combination thereof.

Then, as illustrated in FIGS. 3J_b and 3J_c, the contacts 160 are formed over the silicide layer 145 to form at least one semiconductor structure 300. The contacts 160 may be formed of a metal including Ru, Mo, Co, Ni, W, Ti, Ta, Cu, Al, TiN, TaN or a combination thereof. The contact 160 may be formed by any suitable process, such as PVD, CVD, ALD, electroplating, or other suitable methods.

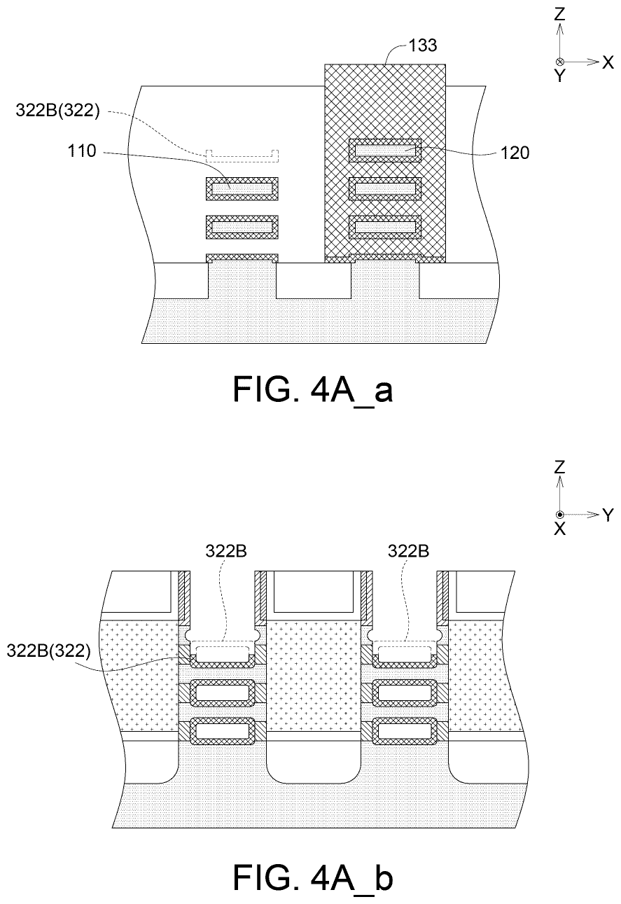

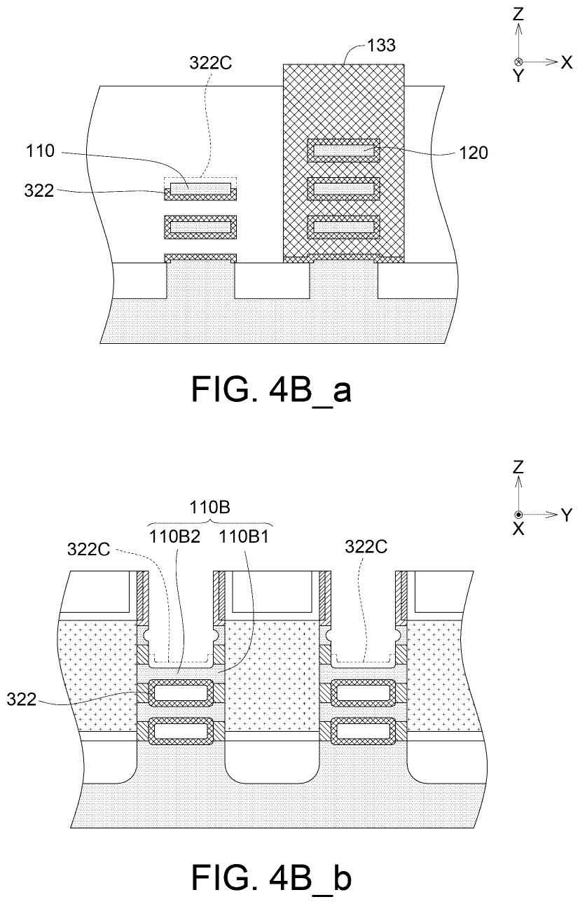

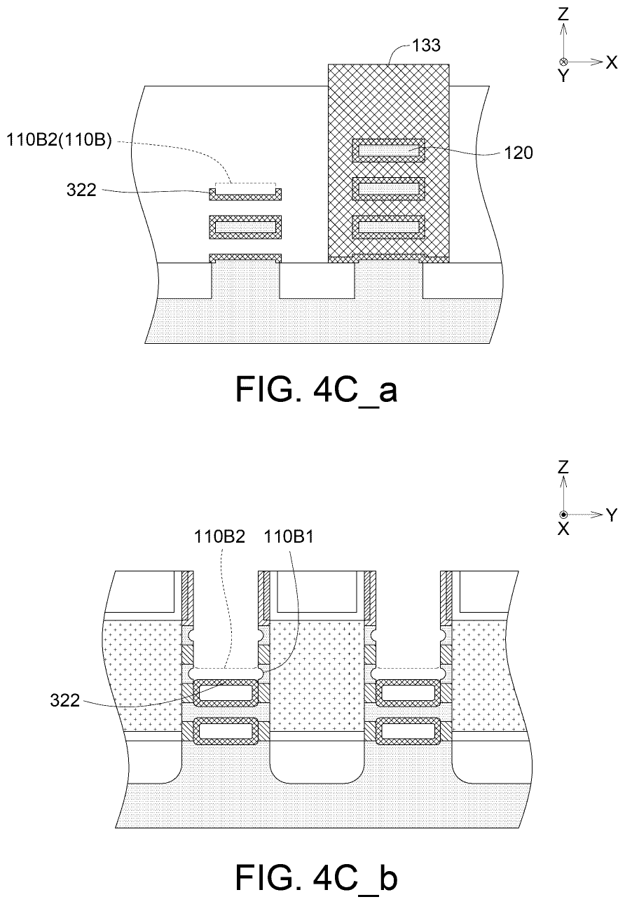

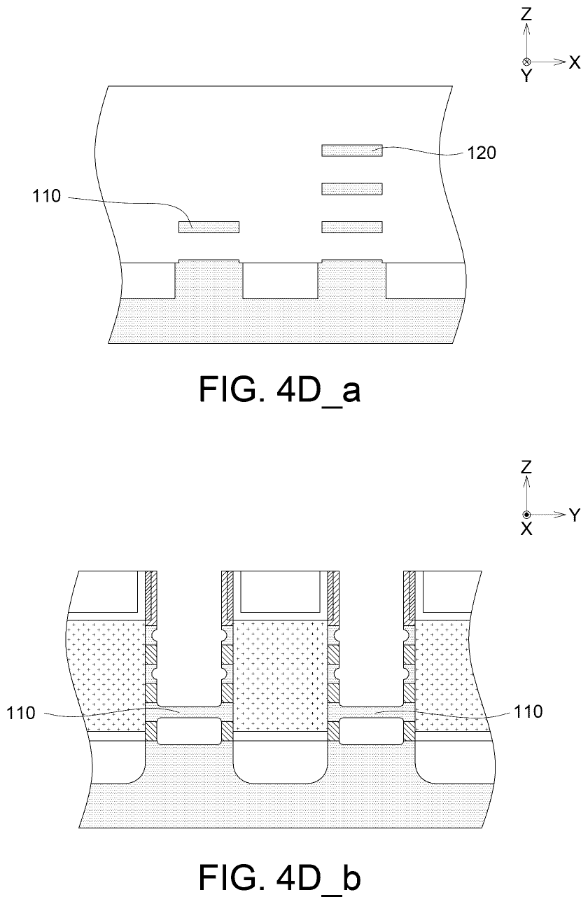

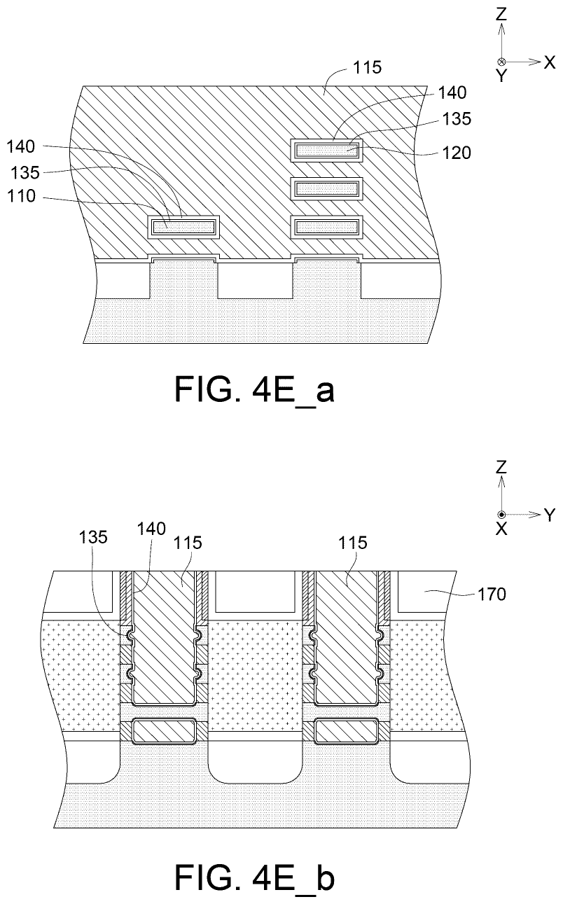

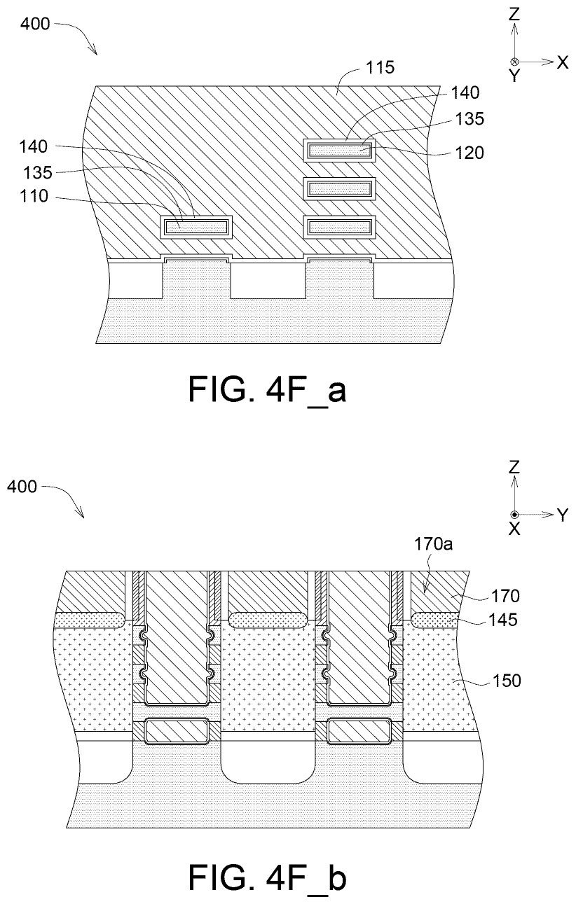

FIGS. 4A_a to 4F_b illustrate schematic diagrams of manufacturing processes of a semiconductor structure 400 according to another embodiment of the present disclosure. The manufacturing processes of the semiconductor structure 400 include the steps the same as or similar to that of the manufacturing processes (for example, corresponding to FIGS. 3A_a to 3G_c) of the semiconductor structure 300, and only the differences will be explained below.

As illustrated in FIGS. 4A_a and 4A_b, after the topmost first active channel 110A in FIG. 3G_a is removed, the topmost portion 322B of the liner 322 is removed by using, for example, dry etching, wet etching, etc.

As illustrated in FIGS. 4B_a and 4B_b, a portion 322C of the liner 322 over the topmost first active channel 110B is removed to expose the topmost first active channel 110B by using, for example, dry etching, wet etching, etc.

In an embodiment, the removal of the portion 322C and the removal of the topmost portion 322B may be performed in the same removal process.

As illustrated in FIGS. 4C_a and 4C_b, the exposed topmost first active channel 110B which is not covered by the liner 322 is removed by using, for example, dry etching, wet etching, etc. As illustrated in FIG. 4C_b, the exposed second portion 110B2 of the topmost first active channel 110B is removed, and the covered first portion 110B1 of the topmost first active channel 110B is retained.

Then, as illustrated in FIGS. 4D_a to 4D_b, the block layer 133 in FIG. 4C_a is removed by using, for example, striping. The striping technique is, for example, dry etching, wet etching, etc. The dry etching is performed in an atmosphere of N₂/O₂, N₂/H₂, etc., and the wet etching is performed in an atmosphere of H₂O₄-, O₃-based, etc. After removal, the liner 322 which covers the second active channels 120 is exposed.

Then, as illustrated in FIGS. 4D_a to 4D_b, the liner 322 in FIGS. 4C_a and 4C_b is removed by using, for example, dry etching, wet etching, etc. After removal, all active channels (110 and 120) are exposed. In an embodiment, there is no residual material of the liner 322 of the structures in FIGS. 4D_a and 4D_b.

Then, as illustrated in FIGS. 4E_a to 4E_b, the interfacial layers 135 are formed in or on the exposed first active channels 110 and the exposed second active channels 120 by using, for example, deposition. In an embodiment, the interfacial layer 135 is formed a material including, for example, SiO₂, SiON, HfSiOx, LaSiOx, YSiOx, AlSiOx, etc., and the interfacial layer 135 has a thickness ranging 0.2 nm and 2 nm. The interfacial layer 135 may be deposited by any appropriate method, such as ALD, CVD, and/or PVD. Due to the recess 110A1r of the first portion 110A1 of the topmost first active channel 110A, the interfacial layer 135 complies with a shape of the recess 110A1r to form the recess 135r.

Then, as illustrated in FIGS. 4E_a to 4E_b, the gate dielectric layer 140 over the inner spacers 120, the poly spacers 130 and the interfacial layers 135 is formed. The gate dielectric layer 140 may be formed in the same process, for example, deposition, such as ALD, CVD, metal-organic CVD, PVD or a combination thereof. Similarly, due to the recess 135r of the interfacial layer 135, the gate dielectric layer 140 complies with a shape of the recess 135r to form the recess 140r.

Then, as illustrated in FIGS. 4F_a to 4F_b, a hole 170a extending to the source/drain layer 150 is formed in the ILD 170 in FIG. 3I_b by using, for example, photolithography, etching, etc. Then, the silicide layers 145 in or on the exposed source/drain layers 150 are formed by using, for example, deposition. The silicide layer 145 may be a metal or metal alloy silicide, and the metal includes a noble metal, a refractory metal, a rare earth metal, alloys thereof, or combinations thereof. For n-channel FET, the silicide layer 145 may include one or more of TiSi, CrSi, TaSi, MoSi, ZrSi, HfSi, ScSi, Ysi, HoSi, TbSI, GdSi, LuSi, DySi, ErSi, Yb Si or a combination thereof. For p-channel FET, the silicide layer 145 may include one or more of NiSi, CoSi, MnSi, Wsi, Fe Si, RhSi, PdSi, RuSi, PtSi, IrSi, OsSi or a combination thereof.

Then, as illustrated in FIGS. 4F_a to 4F_b, the contacts 160 are formed over the silicide layer 145 to form at least one semiconductor structure 400. The contacts 160 may be formed of a metal including Ru, Mo, Co, Ni, W, Ti, Ta, Cu, Al, TiN, TaN or a combination thereof. The contact 160 may be formed by any suitable process, such as PVD, CVD, ALD, electroplating, or other suitable methods.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor structure includes a plurality of first active channels vertically stacked to each other and a plurality of second active channels vertically stacked to each other. In an embodiment, the number of the first active channels and the number of the second active channels are different. As a result, the effective capacitance may be decreased to lead to power efficiency improvement by hybrid sheet approach.

Example embodiment 1: a manufacturing method for a semiconductor structure includes the following steps: forming a plurality of first active channels on a substrate, wherein the first active channels are vertically stacked to each other; forming a plurality of second active channels on the substrate, wherein the second active channels are vertically stacked to each other; forming a liner over the first active channels and the second active channels; removing a portion of the liner to expose the topmost first active channel; and removing the topmost two first active channels.

Example embodiment 2 based on Example embodiment 1: the manufacturing method further includes: after removing the topmost two first active channels, removing the liner to expose the first active channels and the second active channels.

Example embodiment 3 based on Example embodiment 1: in removing the topmost two first active channels, a remaining portion of one of the first active channels forms a recess and a lateral surface, wherein the recess is recessed relative to the lateral surface.

Example embodiment 4 based on Example embodiment 3: the manufacturing method further includes: forming an interfacial layer on the recess, wherein the interfacial layer has a recess which complies with a shape of the recess of the remaining portion.

Example embodiment 5 based on Example embodiment 4: the manufacturing method further includes: forming a block layer to cover another portion of the liner which encapsulates the second active channels.

Example embodiment 6 based on Example embodiment 5: the manufacturing method further includes: after removing the topmost two first active channels, removing the block layer.

Example embodiment 7: a semiconductor structure includes a substrate, a shallow trench isolation (STI), a plurality of first active channels and a plurality of second active channels. The substrate includes a first protrusion, a second protrusion and a trench, wherein the trench is located between the first protrusion and the second protrusion. The shallow trench isolation is disposed in the trench. The first active channels are disposed on the first protrusion and vertically stacked to each other. The second active channels are disposed on the second protrusion and vertically stacked to each other. The number of the first active channels and the number of the second active channels are different.

Example embodiment 8 based on Example embodiment 7: a difference between the number of the first active channels and the number of the second active channels is one or two.

Example embodiment 9 based on Example embodiment 7: the semiconductor structure further includes an inner spacer and a semiconductor portion. The inner spacer is disposed over the topmost first active channel. The semiconductor portion is disposed over the inner spacer and has a recess. The semiconductor portion is formed of a material the same as that of the first active channels.

Example embodiment 10 based on Example embodiment 9: the semiconductor structure further includes an inner spacer and a semiconductor portion. The inner spacer is disposed over the topmost first active channel. The semiconductor portion is disposed over the inner spacer and has a recess. The semiconductor portion is formed of a material the same as that of the first active channels.

Example embodiment 11 based on Example embodiment 10: the semiconductor structure further includes an interfacial layer. The interfacial layer is disposed on the recess and has a recess which complies with a shape of the recess of the semiconductor portion.

Example embodiment 12 based on Example embodiment 10: the semiconductor structure further includes a gate dielectric layer. The gate dielectric layer is disposed on the recess and has a recess which complies with a shape of the recess of the semiconductor portion.

Example embodiment 13: a manufacturing method for a semiconductor structure includes the following steps: forming a plurality of first active channels on a substrate, wherein the first active channels are vertically stacked to each other; and forming a plurality of second active channels on the substrate, wherein the second active channels are vertically stacked to each other. The number of the first active channels and the number of the second active channels are different.

Example embodiment 14 based on Example embodiment 13: the manufacturing method further includes: forming a liner over the first active channels and the second active channels; and removing a portion of the liner to expose the topmost first active channel.

Example embodiment 15 based on Example embodiment 14: the manufacturing method further includes: removing the topmost first active channel.

Example embodiment 16 based on Example embodiment 14: the manufacturing method further includes: removing the liner to expose the first active channels and the second active channels.

Example embodiment 17 based on Example embodiment 13: the manufacturing method further includes: forming a liner over the first active channels and the second active channels; forming a block layer to cover a portion of the liner which encapsulates the second active channels; and removing another portion of the liner to expose the topmost first active channel.

Example embodiment 18 based on Example embodiment 17: the manufacturing method further includes: removing the block layer to expose the portion of the liner which encapsulates the second active channels; and removing the liner to expose the first active channels and the second active channels.

Example embodiment 19 based on Example embodiment 15: in removing the topmost first active channel, a portion of the topmost first active channel forms a recess, and the recess is recessed relative to a lateral surface of the portion of the topmost first active channel.

Example embodiment 20 based on Example embodiment 19: the manufacturing method further includes: forming an interfacial layer on the recess, wherein the interfacial layer has a recess which complies with a shape of the recess of the portion of the topmost first active channel.

Example embodiment 21: a semiconductor structure includes a substrate, a plurality of first active channels and a plurality of second active channels. The first active channels are disposed on the substrate and vertically stacked to each other. The second active channels are disposed on the substrate and vertically stacked to each other. The number of the first active channels and the number of the second active channels are different.

Example embodiment 22 based on Example embodiment 21: a difference between the number of the first active channels and the number of the second active channels is one or two.

Example embodiment 23 based on Example embodiment 21: the semiconductor structure further includes an inner spacer and a semiconductor portion. The inner spacer is disposed over the topmost first active channel. The semiconductor portion is disposed over the inner spacer and has a recess. The semiconductor portion is formed of a material the same as that of the first active channels.

Example embodiment 24 based on Example embodiment 21: the semiconductor structure further includes an inner spacer and a semiconductor portion. The inner spacer disposed is disposed over the topmost first active channel. The semiconductor portion is disposed over the inner spacer and having a lateral surface and a recess, wherein the recess is recessed relative to the lateral surface.

Example embodiment 25 based on Example embodiment 24: the semiconductor structure further includes an interfacial layer. The interfacial layer is disposed on the recess and has a recess which complies with a shape of the recess of the semiconductor portion.

Example embodiment 26 based on Example embodiment 24: the semiconductor structure further includes a gate dielectric layer. The gate dielectric layer is disposed on the recess and has a recess which complies with a shape of the recess of the semiconductor portion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A manufacturing method for a semiconductor structure, comprising:
forming a plurality of first active channels on a substrate, wherein the first active channels are vertically stacked to each other;
forming a plurality of second active channels on the substrate, wherein the second active channels are vertically stacked to each other;
forming a liner over the first active channels and the second active channels;
removing a portion of the liner to expose the topmost first active channel; and
removing the topmost two first active channels.

2. The manufacturing method as claimed in claim 1, further comprising:
after removing the topmost two first active channels, removing the liner to expose the first active channels and the second active channels.

3. The manufacturing method as claimed in claim 1, in removing the topmost two first active channels, a remaining portion of one of the first active channels forms a recess and a lateral surface, wherein the recess is recessed relative to the lateral surface.

4. The manufacturing method as claimed in claim 3, further comprising:
forming an interfacial layer on the recess, wherein the interfacial layer has a recess which complies with a shape of the recess of the remaining portion.

5. The manufacturing method as claimed in claim 4, further comprising:
forming a block layer to cover another portion of the liner which encapsulates the second active channels.

6. The manufacturing method as claimed in claim 5, further comprising:
after removing the topmost two first active channels, removing the block layer.

7. A semiconductor structure, comprising:
a substrate comprising a first protrusion, a second protrusion and a trench, wherein the trench is located between the first protrusion and the second protrusion;
a shallow trench isolation (STI) in the trench;
a plurality of first active channels on the first protrusion and vertically stacked to each other; and
a plurality of second active channels on the second protrusion and vertically stacked to each other;
wherein the number of the first active channels and the number of the second active channels are different.

8. The semiconductor structure as claimed in claim 7, wherein a difference between the number of the first active channels and the number of the second active channels is one or two.

9. The semiconductor structure as claimed in claim 7, further comprising:
an inner spacer disposed over the topmost first active channel; and
a semiconductor portion disposed over the inner spacer and having a recess;
wherein the semiconductor portion is formed of a material the same as that of the first active channels.

10. The semiconductor structure as claimed in claim 7, further comprising:
an inner spacer disposed over the topmost first active channel; and
a semiconductor portion disposed over the inner spacer and having a lateral surface and a recess, wherein the recess is recessed relative to the lateral surface.

11. The semiconductor structure as claimed in claim 10, further comprising:
an interfacial layer on the recess and having a recess which complies with a shape of the recess of the semiconductor portion.

12. The semiconductor structure as claimed in claim 10, further comprising:
a gate dielectric layer on the recess and having a recess which complies with a shape of the recess of the semiconductor portion.

13. A manufacturing method for a semiconductor structure, comprising:
forming a plurality of first active channels on a substrate, wherein the first active channels are vertically stacked to each other; and
forming a plurality of second active channels on the substrate, wherein the second active channels are vertically stacked to each other;
wherein the number of the first active channels and the number of the second active channels are different.

14. The manufacturing method as claimed in claim 13, further comprising:
forming a liner over the first active channels and the second active channels; and
removing a portion of the liner to expose the topmost first active channel.

15. The manufacturing method as claimed in claim 14, further comprising:
removing the topmost first active channel.

16. The manufacturing method as claimed in claim 14, further comprising:
removing the liner to expose the first active channels and the second active channels.

17. The manufacturing method as claimed in claim 13, further comprising:
forming a liner over the first active channels and the second active channels;
forming a block layer to cover a portion of the liner which encapsulates the second active channels; and
removing another portion of the liner to expose the topmost first active channel.

18. The manufacturing method as claimed in claim 17, further comprising:
removing the block layer to expose the portion of the liner which encapsulates the second active channels; and
removing the liner to expose the first active channels and the second active channels.

19. The manufacturing method as claimed in claim 15, wherein in removing the topmost first active channel, a portion of the topmost first active channel forms a recess, and the recess is recessed relative to a lateral surface of the portion of the topmost first active channel.

20. The manufacturing method as claimed in claim 19, further comprising:
forming an interfacial layer on the recess, wherein the interfacial layer has a recess which complies with a shape of the recess of the portion of the topmost first active channel.
